(19) United States
(12) Patent Application Publication
(10) Pub. No.: US 2025/0343123 A1
(43) Pub. Date: Nov. 6, 2025

(54) INTEGRATED CIRCUIT PACKAGE AND METHOD

(71) Applicant: Taiwan Semiconductor Manufacturing Co. Ltd., Hsinchu (TW)

(72) Inventors: Yan-Zuo Tsai, Hsinchu (TW); Ming-Tsu Chung, Hsinchu (TW); Yang-Chih Hsueh, Hsinchu (TW); Yung-Chi Lin, Su-Lin (TW)

(21) Appl. No.: 19/268,258

(22) Filed: Jul. 14, 2025

Related U.S. Application Data
(63) Continuation of application No. 18/404,266, filed on Jan. 4, 2024.
(60) Provisional application No. 63/519,355, filed on Aug. 14, 2023.
(60) Provisional application No. 63/608,957, filed on Dec. 12, 2023.

(51) Int. Cl. H01L 23/498; H01L 21/48; H01L 21/768; H01L 23/16; H01L 23/528

(52) U.S. Cl. CPC H01L 23/49827; H01L 21/486; H01L 21/76898; H01L 23/16; H01L 23/5283

(57) ABSTRACT

A package includes a first die over and bonded to a first side of a second die, where the second die includes a first substrate, a first interconnect structure over the first substrate, a seal ring disposed within the first interconnect structure, first dummy through substrate vias (TSVs) extending through edge regions of the first substrate of the second die and in physical contact with the seal ring, and functional TSVs extending through a central region of the first substrate of the second die.

### CROSS-REFERENCE TO RELATED APPLICATIONS

This application is a continuation of U.S. application Ser. No. 18/404,266, filed on Jan. 4, 2024, which claims the benefit of U.S. Provisional Application No. 63/519,355, filed on Aug. 14, 2023 and U.S. Provisional Application No. 63/608,957, filed on Dec. 12, 2023, which applications are hereby incorporated herein by reference.

### BACKGROUND

Semiconductor devices are used in a variety of electronic applications, such as personal computers, cell phones, digital cameras, and other electronic equipment, as examples. Semiconductor devices are typically fabricated by sequentially depositing insulating or dielectric layers, conductive layers, and semiconductive layers of material over a semiconductor substrate, and patterning the various material layers using lithography to form circuit components and elements thereon. Dozens or hundreds of integrated circuits are typically manufactured on a single semiconductor wafer. The individual dies are singulated by sawing the integrated circuits along a scribe line. The individual dies are then packaged separately, in multi-chip modules, or in other types of packaging, for example.

The semiconductor industry continues to improve the integration density of various electronic components (e.g., transistors, diodes, resistors, capacitors, etc.) by continual reductions in minimum feature size, which allow more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A through 2 illustrate cross-sectional views and a top-down view of intermediate steps during a process for forming a semiconductor die, in accordance with some embodiments.

FIGS. 3 through 6 illustrate cross-sectional views and top-down views of intermediate steps during a process for forming a semiconductor die, in accordance with other embodiments.

FIGS. 7 through 9 illustrate cross-sectional views of intermediate steps during a process for forming an integrated chip package, in accordance with some embodiments.

FIGS. 10A and 10B illustrate a cross-sectional view and a top-down view of intermediate steps during a process for forming a semiconductor die, in accordance with some embodiments.

FIGS. 11A and 11B illustrate a cross-sectional view and a top-down view of intermediate steps during a process for forming a semiconductor die, in accordance with some embodiments.

FIGS. 12 through 16 illustrate cross-sectional views and top-down views of intermediate steps during a process for forming a semiconductor die, in accordance with other embodiments.

FIGS. 17 through 21 illustrate cross-sectional views of intermediate steps during a process for forming an integrated chip package, in accordance with some embodiments.

FIGS. 22 illustrates a cross-sectional view of intermediate steps during a process for forming an integrated chip package, in accordance with other embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments provide methods applied to forming a 3D integrated chip (3DIC) package, such as a system on integrated chip (SoIC) package. Forming the integrated chip package comprises bonding a semiconductor die (e.g., a top die) to a semiconductor wafer (e.g., a bottom die). The top die may comprise dummy through substrate vias (TSVs) that are disposed at peripheral regions (also referred to as edge regions) of the top die. The semiconductor wafer may also comprise dummy through substrate vias (TSVs) that are disposed at peripheral regions (also referred to as edge regions) of the semiconductor wafer. For example, the dummy TSVs may be uniformly distributed within the top die along the edge regions of the top die. The dummy TSVs may be also uniformly distributed within the semiconductor wafer along the edge regions of the semiconductor wafer. The dummy TSVs comprise a metal and are used to increase a metal density of the edge regions of the top die, and reduce a difference between the metal density of the edge regions of the top die and a metal density of a central region of the top die. Advantageous features of one or more embodiments disclosed herein may include reducing a difference between a co-efficient of thermal expansion (CTE) of the edge regions of the top die and a co-efficient of thermal expansion (CTE) of the central region of the top die. This allows for a reduction of thermal stresses that are generated within the top die, and as a result, there is a reduced risk of warping of the top die. This ensures that the edge regions of the top die do not curve (also referred to as tilt) upwards away from a top surface of the semiconductor wafer, and allows adequate physical contact between bonding pads of the edge regions of the top die, and respective bonding pads of the semiconductor wafer. In this way, bonding between the top die and the semiconductor wafer is improved, and device reliability is enhanced. In addition, preventing the edge regions of the top die from tilting upwards away from the top surface of the semiconductor wafer reduces a risk of forming a gap between the top die and the semiconductor wafer. As a result, a risk of chemical damage or moisture damage to the exposed surfaces of the top die and the semiconductor wafer within the gap during subsequently performed processing steps is reduced.

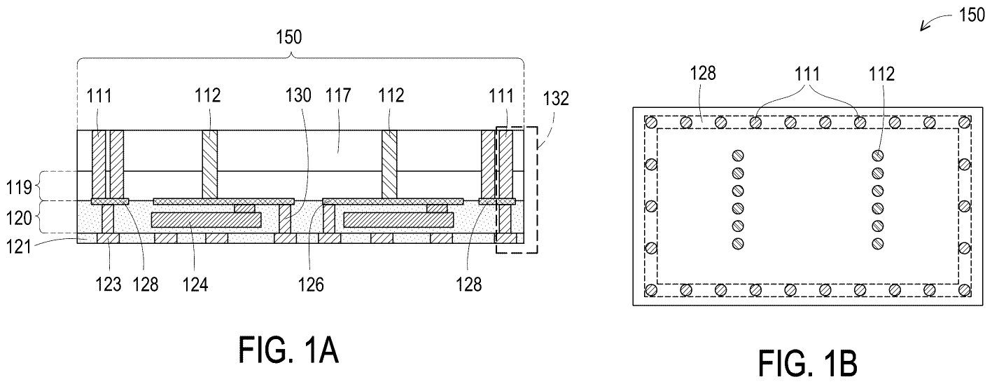

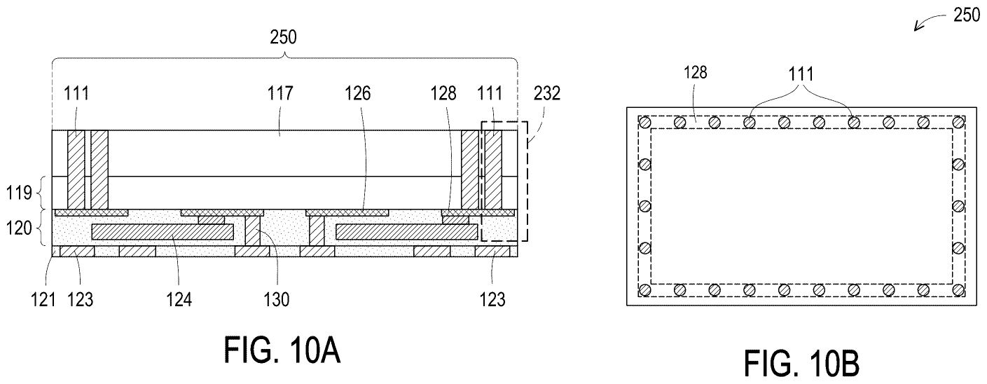

FIGS. 1A through 9 illustrate cross-sectional views of intermediate steps during a process for forming an integrated chip package 10, in accordance with some embodiments. FIGS. 10A through 21 illustrate cross-sectional views of intermediate steps during a process for forming an integrated chip package 20, in accordance with some embodiments. In FIGS. 1A and 1B, a semiconductor die 150 is illustrated. FIG. 1A illustrates a cross-sectional view of the semiconductor die 150. FIG. 1B illustrates a top-down view of the semiconductor die 150. The semiconductor die 150 may be referred to subsequently as a top die. The semiconductor die 150 may be a logic die (e.g., application processor (AP), central processing unit, microcontroller, etc.), a memory die (e.g., dynamic random access memory (DRAM) die, hybrid memory cube (HBC), a static random access memory (SRAM) die, a wide input/output (wideIO) memory die, a magnetoresistive random access memory (mRAM) die, a resistive random access memory (rRAM) die, etc.), a power management die (e.g., power management integrated circuit (PMIC) dies), a radio frequency (RF) die, a sensor die, a micro-electro-mechanical-system (MEMS) die, a signal processing die (e.g., digital signal processing (DSP) die), a front-end die (e.g., analog front-end (AFE) die), a biomedical die, or the like. The semiconductor die 150 may also be a System-on-Chip (SoC) die, or the like. The semiconductor die 150 may include a substrate 117 (e.g., a semiconductor substrate), an interconnect structure 119 disposed on the substrate 117, a dielectric layer 120 disposed on the interconnect structure 119, a bonding layer 121 disposed on the dielectric layer 120, and bonding pads 123 disposed in the bonding layer 121 and exposed at the front surface of the semiconductor die 150. The side of the semiconductor die 150 comprising the exposed bonding pads 123 and the bonding layer 121 may also be referred to subsequently as the front side of the semiconductor die 150. The side of the semiconductor die 150 comprising an exposed back side surface of the substrate 117 may also be referred to subsequently as the back side of the semiconductor die 150.

The substrate 117 of the semiconductor die 150 may include a crystalline silicon wafer. The substrate 117 may include various doped regions depending on design requirements (e.g., p-type substrate or n-type substrate). In some embodiments, the doped regions may be doped with p-type or n-type dopants. The doped regions may be doped with p-type dopants, such as boron or BF₂; n-type dopants, such as phosphorus or arsenic; and/or combinations thereof. The doped regions may be configured for n-type Fin-type Field Effect Transistors (FinFETs) and/or p-type FinFETs. In some alternative embodiments, the substrate 117 may comprise an active layer of a semiconductor-on-insulator (SOI) substrate. The substrate 117 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used.

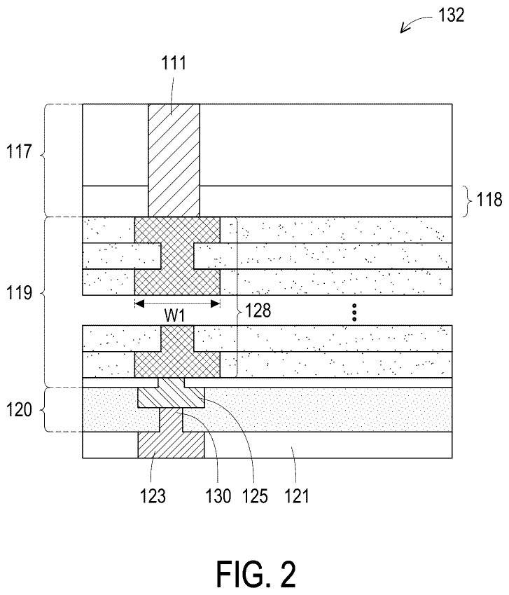

Active and/or passive devices, such as transistors, diodes, capacitors, resistors, etc., may be formed in and/or on the substrate 117. For example, these active and/or passive devices may be formed in a front-end of Line (FEOL) layer 118 (shown subsequently in FIGS. 2 through 4A) of the substrate 117. The devices may be interconnected by the interconnect structure 119. The interconnect structure 119 electrically connects the devices on the substrate 117 to form one or more integrated circuits. The interconnect structure 119 may include one or more dielectric layers (for example, one or more interlayer dielectric (ILD) layers, intermetal dielectric (IMD) layers, or the like) and metallization patterns 126 (which may also be referred to as interconnect wirings subsequently) embedded in the one or more dielectric layers. The material of the one or more dielectric layers may include silicon oxide (SiOₓ, where x>0), silicon nitride (SiNₓ, where x>0), silicon oxynitride (SiOₓN_{y}, where x>0 and y>0), or other suitable dielectric material. The metallization patterns 126 may include metallic wirings. For example, the metallization patterns 126 may include copper wirings, copper pads, aluminum pads or combinations thereof that are formed by one or more single damascene processes, dual damascene processes, or the like. In addition, the interconnect structure 119 may comprise a seal ring 128, that comprises copper, aluminum, or the like. The seal ring 128 may be formed at the same time as the metallization patterns 126, and using the same processes and materials that were used for the formation of the metallization patterns 126. The seal ring 128 (shown in ghost in FIG. 1B) is disposed within the interconnect structure 119 and adjacent to the edges (e.g., close to the periphery) of the semiconductor die 150, and surrounds the metallization patterns 126 within the interconnect structure 119.

The semiconductor die 150 further comprises functional through substrate vias (TSVs) 112 which may be electrically connected to the metallization patterns 126 in the interconnect structure 119. The TSVs 112 may extend through the substrate 117, and may be disposed in a central region (e.g., as shown in FIG. 1B) of the semiconductor die 150. In an embodiment, the TSVs 112 may also extend partially or completely through the interconnect structure to electrically connect to the metallization patterns 126. In addition, the semiconductor die 150 comprises dummy through substrate vias (TSVs) 111 which extend through the substrate 117. The dummy TSVs 111 may also extend partially or completely through the interconnect structure 119. In an embodiment, the dummy TSVs 111 may not serve a functional electrical or interconnect purpose. The dummy TSVs 111 may be uniformly distributed within the semiconductor die 150 along the edge regions of the semiconductor die 150. In an embodiment, the dummy TSVs 111 may be arranged along the seal ring 128 (shown in ghost in FIG. 1B), such that each dummy TSV 111 overlaps the seal ring 128. For example, pairs of dummy TSVs 111 (e.g., as shown in FIG. 1A) may be uniformly distributed (e.g., disposed at regular intervals) above and along the seal ring 128, wherein bottom surfaces of the dummy TSVs 111 are in physical contact with the seal ring 128. In other embodiments, single ones of the dummy TSVs 111 are uniformly distributed (e.g., disposed at regular intervals) above and along the seal ring 128, wherein bottom surfaces of the dummy TSVs 111 are in physical contact with the seal ring 128. The dummy TSVs 111 may be disposed adjacent to the edges (e.g., close to the periphery) of the semiconductor die 150, wherein the dummy TSVs 111 are disposed to be around the TSVs 112 that may be disposed within a central region of the semiconductor die 150. In addition, the seal ring 128 within the interconnect structure 119 is disposed adjacent to the edges (e.g., close to the periphery) of the semiconductor die 150, wherein the seal ring 128 surrounds the metallization patterns 126. The dummy TSVs 111 and the TSVs 112 may comprise copper, tungsten, aluminum, silver, gold, a combination thereof, and/or the like. The TSVs 112 provide electrical connection from a back side of the substrate 117 to a front side of the substrate 117.

Referring further to FIGS. 1A and 1B, the dielectric layer 120 may be disposed on the interconnect structure 119. The dielectric layer 120 may comprise silicon oxide, silicon nitride, or the like, and is formed using a chemical vapor deposition (CVD) process, an atomic layer deposition (ALD) process, or the like. In an embodiment, the dielectric layer 120 may comprise two or more dielectric sub-layers. The semiconductor die 150 may further comprise one or more contact pads 124 to which external connections are made to the interconnect structure 119, the metallization patterns 126, and the devices in and/or on the substrate 117. The one or more contact pads 124 may be embedded within the dielectric layer 120. To form the contact pads 124, openings for the contact pads 124 are first formed in the dielectric layer 120 using acceptable photolithography and etching techniques. A conductive material may then be formed in the openings using a deposition process such as sputtering, evaporation, CVD, plasma-enhanced chemical vapor deposition (PECVD), a plating process, an electroless plating process, a combination thereof, or the like. The conductive material may comprise copper, aluminum, or another conductive material.

Bonding pad vias (BPVs) 130 may also be formed to extend through the dielectric layer 120. The BPVs 130 may be formed by first forming first openings and second openings in the dielectric layer 120 by, for example, etching, or the like. The first openings may expose surfaces of the seal ring 128 or surfaces of respective contact pads 125 (shown subsequently in FIG. 2) if present, and the second openings may expose surfaces (e.g., surfaces of contact pads) of the metallization patterns 126. A conductive material is then deposited in the first openings and the second openings. The conductive material may be formed by an electro-chemical plating process, CVD, ALD, PVD, a combination thereof, and/or the like. Examples of conductive materials are copper, aluminum, silver, gold, a combination thereof, and/or the like. Excess conductive material may be removed from the front side of the semiconductor die 150 by, for example, chemical mechanical polishing. The remaining conductive material in the first openings form first BPVs 130 that are in physical contact with the seal ring 128 or respective contact pads 125 (if present). The remaining conductive material in the second openings form second BPVs 130 that are in physical and electrical contact with the metallization patterns 126. In an embodiment, the first BPVs 130 may be optional and are not formed, and only the second BPVs 130 are formed.

The bonding layer 121 is disposed on the dielectric layer 120, and may comprise a dielectric layer. Bonding pads 123 (e.g. first bonding pads 123 and second bonding pads 123) are embedded in the bonding layer 121, wherein the second bonding pads 123 allow electrical connection to be made to the metallization patterns 126 of the interconnect structure 119, the TSVs 112, the contact pads 124, and the devices in or on the substrate 117 through the second BPVs 130 that extend through the dielectric layer 120. The first bonding pads 123 may be electrically connected to the dummy TSVs 111 through the first BPVs 130, the contact pads 125 (shown subsequently in FIG. 2) if present and the seal ring 128. The first bonding pads 123 and the first BPVs 130 are optional and may not be present in some embodiments. The material of the bonding layer 121 may be silicon oxide (SiOₓ, where x>0), silicon nitride (SiNₓ, where x>0), silicon oxynitride (SiOₓN_{y}, where x>0 and y>0), tetraethyl orthosilicate (TEOS), or other suitable dielectric material, and the bonding pads 123 may comprise conductive pads (e.g., copper pads), conductive vias (e.g., copper vias), or combinations thereof. The bonding layer 121 may be formed by depositing a dielectric material on the dielectric layer 120 and the BPVs 130 using a CVD process (e.g., a plasma enhanced CVD process or other suitable process); patterning the dielectric material to form the bonding layer 121 including openings or through holes; and filling conductive material in the openings or through holes defined in the bonding layer 121 to form the bonding pads 123 embedded in the bonding layer 121.

FIG. 2 illustrates an edge region 132 of the semiconductor die 150 shown in FIG. 1A, in accordance with an embodiment. To form the semiconductor die 150, the FEOL layer 118 is first formed in and/or on a front side of the substrate 117. A side of the substrate 117 that is opposite the front side of the substrate may be referred to as the back side of the substrate 117. The FEOL layer 118 comprises active and/or passive devices, such as transistors, diodes, capacitors, resistors, or the like. After the formation of the FEOL layer 118, the dummy TSVs 111 and the TSVs 112 are then formed to extend entirely through the substrate 117 (e.g., including the FEOL layer 118). The dummy TSVs 111 and the TSVs 112 may be formed by first forming openings in the front side of the substrate 117 that extend partially through the substrate 117 (e.g., including the FEOL layer 118) by, for example, etching, milling, laser techniques, a combination thereof, and/or the like. A thin barrier layer (not shown in the Figures) may be conformally deposited in the openings, such as by chemical vapor deposition (CVD), atomic layer deposition (ALD), physical vapor deposition (PVD), thermal oxidation, a combination thereof, and/or the like. The barrier layer may comprise a nitride or an oxynitride, such as titanium nitride, titanium oxynitride, tantalum nitride, tantalum oxynitride, tungsten nitride, a combination thereof, and/or the like. A conductive material is deposited over the thin barrier layer and in the openings. The conductive material may be formed by an electro-chemical plating process, CVD, ALD, PVD, a combination thereof, and/or the like. Examples of conductive materials are copper, tungsten, aluminum, silver, gold, a combination thereof, and/or the like. Excess conductive material and barrier layer may be removed from the front side of the substrate 117 by, for example, chemical mechanical polishing. Thus, in some embodiments, the dummy TSVs 111 and the TSVs 112 may comprise a conductive material and a thin barrier layer between the conductive material and the substrate 117. In subsequent processing steps, the back side of the substrate 117 may be thinned to expose the dummy TSVs 111 and the TSVs 112. After thinning, the TSVs 112 provide electrical connection from a back side of the substrate 117 to a front side of the substrate 117. The dummy TSVs 111 may be uniformly distributed within the substrate 117 along the edge regions of the semiconductor die 150, while the TSVs 112 are disposed within the substrate 117 in a central region of the semiconductor die 150. In this way, as seen in FIGS. 1A, 1B and 2, the dummy TSVs 111 are disposed adjacent to the edges (e.g., close to the periphery) of the semiconductor die 150, and are disposed to be around the TSVs 112.

After the formation of the dummy TSVs 111 and the TSVs 112, the interconnect structure 119 is then formed on the front side of the substrate 117. The interconnect structure 119 may include one or more dielectric layers (for example, one or more interlayer dielectric (ILD) layers, intermetal dielectric (IMD) layers, or the like) and metallization patterns 126 embedded in the one or more dielectric layers. The material of the one or more dielectric layers may include silicon oxide (SiOₓ, where x>0), silicon nitride (SiNₓ, where x>0), silicon oxynitride (SiOₓN_{y}, where x>0 and y>0), or other suitable dielectric material, that is formed using a CVD process, an ALD process, or the like. Each dielectric layer may be patterned using acceptable photolithography and etching techniques to form openings that correspond to a desired pattern for a metallization pattern 126 that is to be formed extending along the major surface of the dielectric layer and extending through the dielectric layer. A conductive material is then formed in the openings in the dielectric layer to form the metallization pattern 126 using for example, a PVD process, electroplating, electroless plating, a combination thereof, or the like. The conductive material may comprise a metal, like copper, titanium, tungsten, aluminum, a combination thereof, or the like. The metallization patterns 126 are used to electrically connect the TSVs 112 and the devices in the FEOL layer 118 to the subsequently formed contact pads 124, the bonding pad vias (BPVs) 130, and the bonding pads 123.

The interconnect structure 119 also comprises the seal ring 128. The seal ring 128 may be formed in the interconnect structure 119 at the same time as the metallization patterns 126, and using the same processes and materials that were used for the formation of the metallization patterns 126. The seal ring 128 is disposed within the interconnect structure 119 and adjacent to the edges (e.g., close to the periphery) of the semiconductor die 150, and surrounds the metallization patterns 126 within the interconnect structure 119. The seal ring 128 extends vertically through the one or more dielectric layers of the interconnect structure 119 to physically contact the dummy TSVs 111, which are arranged along the seal ring 128 (as shown previously in FIG. 1B). Each dummy TSV 111 therefore overlaps the seal ring 128 when the semiconductor die 150 is oriented in such a way that the substrate 117 is disposed to be vertically above the interconnect structure 119. In an embodiment, a width W1 of the seal ring 128 may vary along the vertical height of the seal ring 128.

After the formation of the interconnect structure 119, first portions of contact pads 125 are formed in one or more dielectric layers of the interconnect structure 119. To form the first portions of the contact pads 125, first openings are first formed in the one or more dielectric layers of the interconnect structure 119 using acceptable photolithography and etching techniques. The first openings expose surfaces of the seal ring 128. A conductive material may then be formed in the first openings using a deposition process such as sputtering, evaporation, CVD, plasma-enhanced chemical vapor deposition (PECVD), a plating process, an electroless plating process, or the like. The conductive material may comprise copper, aluminum, or another conductive material. A planarization process is then performed to remove excess portions of the conductive material, and the remaining conductive material in the first openings forms the first portions of the contact pads 125. In this way, the first portion of each contact pad 125 is embedded in the one or more dielectric layers of the interconnect structure 119.

The dielectric layer 120 (described previously in FIGS. 1A and 1B) is then formed on the interconnect structure 119 and the first portions of the contact pads 125. Second portions of the contact pads 125 are then formed in the dielectric layer 120, such that each second portion of a contact pad 125 is in physical contact with a respective first portion of the contact pad 125. In this way, each second portion of a contact pad 125 is embedded in the dielectric layer 120. To form the second portions of the contact pads 125, second openings are first formed in the dielectric layer 120 using acceptable photolithography and etching techniques. The second openings expose surfaces of respective first portions of the contact pads 125. A conductive material may then be formed in the second openings using a deposition process such as sputtering, evaporation, CVD, plasma-enhanced chemical vapor deposition (PECVD), a plating process, an electroless plating process, or the like. The conductive material may comprise copper, aluminum, or another conductive material. A planarization process is then performed to remove excess portions of the conductive material, and the remaining conductive material in the second openings form the second portions of the contact pads 125. The second portion of each contact pad 125 may have a greater width than its respective first portion of the contact pad 125. Each contact pad 125 is in physical contact with the seal ring 128. Each dummy TSV 111 overlaps a respective contact pad 125 when the semiconductor die 150 is oriented in such a way that the substrate 117 is disposed to be vertically above the interconnect structure 119. Additionally, the one or more contact pads 124 (described previously in FIGS. 1A and 1B) may also be formed in the dielectric layer 120.

After the formation of the contact pads 124, the contact pads 125, and the dielectric layer 120, the BPVs 130 (described previously in FIGS. 1A and 1B) may also be formed to extend through the dielectric layer 120. Each of the first BPVs 130 may be in physical contact with a respective contact pad 125, and each of the second BPVs 130 may be in physical contact with surfaces (e.g., surfaces of contact pads) of the metallization patterns 126.

After the formation of the BPVs 130, the bonding layer 121 and the bonding pads 123 (described previously in FIGS. 1A and 1B) are formed over the dielectric layer 120 and the BPVs 130. The bonding pads 123 (e.g., the first bonding pads 123 and the second bonding pads 123) are embedded in the bonding layer 121, wherein the second bonding pads 123 allow electrical connection to be made to the metallization patterns 126 of the interconnect structure 119, the TSVs 112, the contact pads 124, and the devices in or on the substrate 117 through the second BPVs 130 that extend through the dielectric layer 120. The first bonding pads 123 may be electrically connected to the dummy TSVs 111 through the first BPVs 130, the contact pads 125 and the seal ring 128.

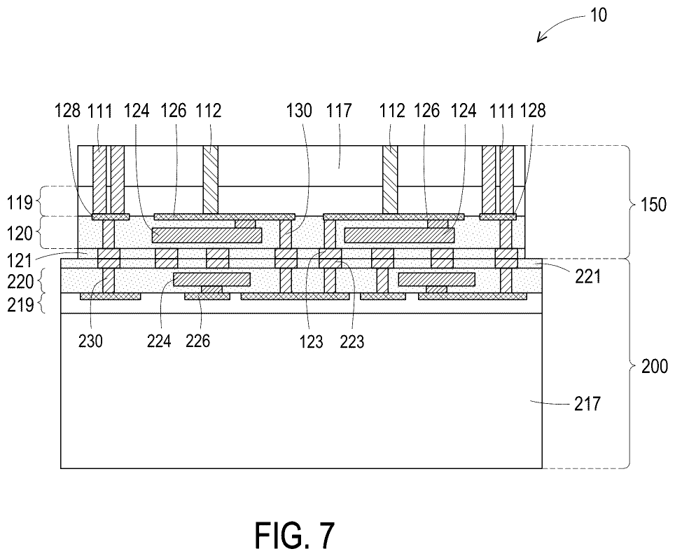

Advantages may be achieved as a result of forming the semiconductor die 150 that comprises the dummy TSVs 111 that are distributed within the semiconductor die 150 along the edge regions of the semiconductor die 150. The dummy TSVs 111 may be arranged along the seal ring 128, such that each dummy TSV 111 overlaps and is in physical contact with the seal ring 128. The dummy TSVs 111 may be disposed at regular intervals (e.g., uniformly distributed) or irregular intervals (e.g., non-uniformly distributed) above and along the seal ring 128, wherein the dummy TSVs 111 are disposed to be around the TSVs 112, the TSVs 112 being disposed within a central region of the semiconductor die 150. These advantages include increasing a metal density of the edge regions of the semiconductor die 150, and reducing a difference between the metal density of the edge regions of the semiconductor die 150 and a metal density of a central region of the semiconductor die 150. This allows for the reducing of a difference between a co-efficient of thermal expansion (CTE) of the edge regions of the semiconductor die 150 and a co-efficient of thermal expansion (CTE) of the central region of the semiconductor die 150. This results in a reduction of thermal stresses that are generated within the semiconductor die 150, and further results in a reduced risk of warping of the semiconductor die 150. This ensures that the edge regions of the semiconductor die 150 do not curve (also referred to as tilt) upwards away from a top surface of a wafer 200 (described subsequently in FIG. 7) to which the semiconductor die 150 is bonded to, and allows adequate physical contact between the bonding pads 123 on the edge regions of the semiconductor die 150, and respective bonding pads 223 on the wafer 200. In this way, bonding between the semiconductor die 150 and the wafer 200 is improved, and device reliability is enhanced. In addition, preventing the edge regions of the semiconductor die 150 from tilting upwards away from the top surface of the wafer 200 reduces a risk of forming a gap between the semiconductor die 150 and the wafer 200. As a result, a risk of chemical damage or moisture damage to the exposed surfaces of the semiconductor die 150 and the wafer 200 within the gap during subsequently performed processing steps is reduced.

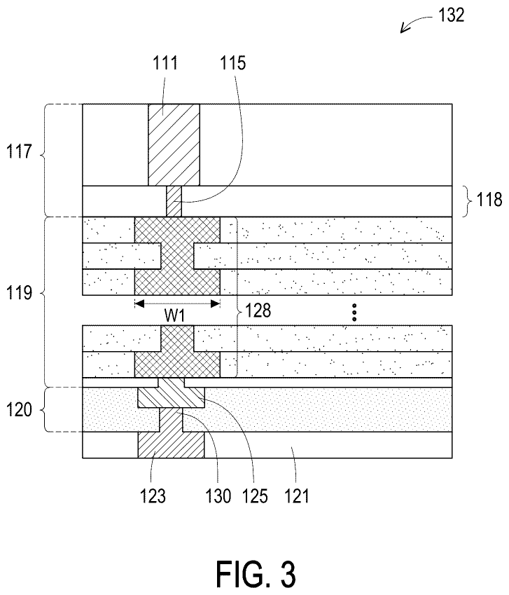

FIG. 3 illustrates the edge region 132 of the semiconductor die 150 shown in FIG. 1A, in accordance with an alternative embodiment. Unless specified otherwise, like reference numerals in this embodiment (and subsequently discussed embodiments) represent like components in the embodiment shown in FIGS. 1A through 2 formed by like processes. Accordingly, the process steps and applicable materials may not be repeated herein.

The semiconductor die 150 shown in the embodiment of FIG. 3 differs from the semiconductor die 150 shown in the embodiment of FIG. 2 in that when forming the semiconductor die 150 shown in the embodiment of FIG. 3, the dummy TSVs 111 are formed first to extend partially through the substrate 117, prior to forming the FEOL layer 118 in and/or on the front side of the substrate 117. The TSVs 112 may be formed after forming the FEOL layer 118 in and/or on the front side of the substrate 117, as described previously in FIG. 2.

A side of the substrate 117 that is opposite the front side of the substrate may be referred to as the back side of the substrate 117. The dummy TSVs 111 are formed to extend partially through the substrate 117. The dummy TSVs 111 may be formed by first forming openings in the back side of the substrate 117 that extend partially through the substrate 117 by, for example, etching, milling, laser techniques, a combination thereof, and/or the like. A thin barrier layer (not shown in the Figures) may be conformally deposited in the openings, such as by chemical vapor deposition (CVD), atomic layer deposition (ALD), physical vapor deposition (PVD), thermal oxidation, a combination thereof, and/or the like. The barrier layer may comprise a nitride or an oxynitride, such as titanium nitride, titanium oxynitride, tantalum nitride, tantalum oxynitride, tungsten nitride, a combination thereof, and/or the like. A conductive material is deposited over the thin barrier layer and in the openings. The conductive material may be formed by an electro-chemical plating process, CVD, ALD, PVD, a combination thereof, and/or the like. Examples of conductive materials are copper, tungsten, aluminum, silver, gold, a combination thereof, and/or the like. Excess conductive material and barrier layer may be removed from the back side of the substrate 117 by, for example, chemical mechanical polishing. Thus, in some embodiments, the dummy TSVs 111 may comprise a conductive material and a thin barrier layer between the conductive material and the substrate 117. After the formation of the dummy TSVs 111, the FEOL layer 118 may be formed in and/or on the front side of the substrate 117.

After the formation of the FEOL layer 118 and the dummy TSVs 111, the TSVs 112 may be formed as described previously in FIG. 2. The dummy TSVs 111 may be uniformly distributed within the substrate 117 along the edge regions of the semiconductor die 150, while the TSVs 112 are disposed within the substrate 117 in a central region of the semiconductor die 150. In this way, as seen in FIGS. 1A, 1B and 3, the dummy TSVs 111 are disposed adjacent to the edges (e.g., close to the periphery) of the semiconductor die 150, and are disposed around the TSVs 112. After the formation of the TSVs 112, the interconnect structure 119 (e.g., comprising the seal ring 128 and the metallization patterns 126) is formed as described previously in FIGS. 1A, 1B, and 2. In addition, after the interconnect structure 119 is formed, the dielectric layer 120, the one or more contact pads 124, the contact pads 125, and the BPVs 130 are formed as described previously in FIGS. 1A, 1B, and 2. Furthermore, after the dielectric layer 120, the one or more contact pads 124, the contact pads 125, and the BPVs 130 are formed, the bonding layer 121 and the bonding pads 123 are formed over the dielectric layer 120 and the BPVs 130 as described previously in FIGS. 1A, 1B, and 2. In an embodiment, each dummy TSV 111 may be electrically connected to the seal ring 128, a respective contact pad 125, a respective first BPV 130, and a respective first bonding pad 123 through a conductive plug 115 that is formed in the FEOL layer 118. In other embodiments, the dummy TSVs 111 may be electrically isolated from the seal ring 128, the contact pads 125, the first BPVs 130, and the first bonding pads 123. In an embodiment, the first bonding pads 123 and the first BPVs 130 are optional and may not be formed.

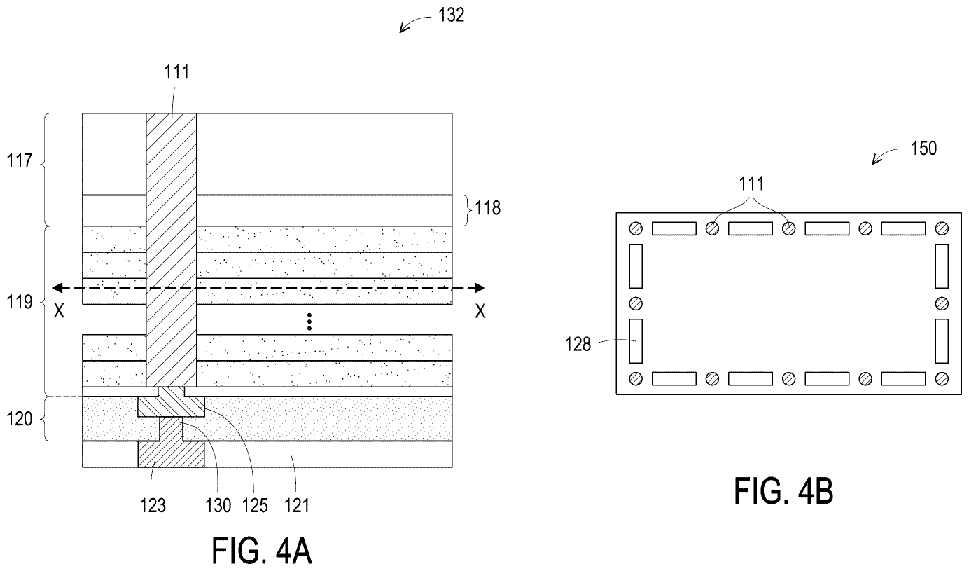

FIG. 4A illustrates the edge region 132 of the semiconductor die 150 shown in FIG. 1A, in accordance with an alternative embodiment. FIG. 4B illustrates a top-down view of the semiconductor die 150 along a cross-section X-X shown in FIG. 4A. Unless specified otherwise, like reference numerals in this embodiment (and subsequently discussed embodiments) represent like components in the embodiment shown in FIGS. 1A through 2 formed by like processes. Accordingly, the process steps and applicable materials may not be repeated herein.

The semiconductor die 150 shown in the embodiment of FIG. 4A differs from the semiconductor die 150 shown in the embodiment of FIG. 2 in that when forming the semiconductor die 150 shown in the embodiment of FIG. 4A, the dummy TSVs 111 are formed after the formation of the FEOL layer 118 in and/or on the front side of the substrate 117, the TSVs 112, and the interconnect structure 119 (e.g., including the seal ring 128 and the metallization patterns 126). The FEOL layer 118 is first formed in and/or on the front side of the substrate 117 as described previously in FIGS. 1A, 1B, and 2. After the FEOL layer 118 has been formed in and/or on the front side of the substrate 117, the TSVs 112 may then be formed as described previously in FIGS. 1A, 1B, and 2.

After the TSVs 112 have been formed, the interconnect structure 119 (including the seal ring 128 and the metallization patterns 126) is then formed as described previously in FIGS. 1A, 1B, and 2. The seal ring 128 may be formed so as to have intermittent gaps in its structure as shown in FIG. 4B. Each gap in the seal ring 128 structure is disposed between adjacent portions of the seal ring 128, and the gaps are filled with a dielectric material of the one or more dielectric layers of the interconnect structure 119.

The dummy TSVs 111 are then formed to extend through the substrate 117 (including the FEOL layer 118), and partially through the interconnect structure 119. Each dummy TSV 111 may extend through a respective gap (e.g., through the dielectric material of the one or more dielectric layers of the interconnect structure 119 disposed within the respective gap) between adjacent portions of the seal ring 128 as shown in FIG. 4B. The dummy TSVs 111 may be formed by first forming openings in the back side of the substrate 117 that extend through the substrate 117, and partially through the interconnect structure 119 (e.g., through the dielectric layers of the interconnect structure 119) by, for example, etching, milling, laser techniques, a combination thereof, and/or the like. A thin barrier layer (not shown in the Figures) may be conformally deposited in the openings, such as by chemical vapor deposition (CVD), atomic layer deposition (ALD), physical vapor deposition (PVD), thermal oxidation, a combination thereof, and/or the like. The barrier layer may comprise a nitride or an oxynitride, such as titanium nitride, titanium oxynitride, tantalum nitride, tantalum oxynitride, tungsten nitride, a combination thereof, and/or the like. A conductive material is deposited over the thin barrier layer and in the openings. The conductive material may be formed by an electro-chemical plating process, CVD, ALD, PVD, a combination thereof, and/or the like. Examples of conductive materials are copper, tungsten, aluminum, silver, gold, a combination thereof, and/or the like. Excess conductive material and barrier layer may be removed from the back side of the substrate 117 by, for example, chemical mechanical polishing. Thus, in some embodiments, the dummy TSVs 111 may comprise a conductive material and a thin barrier layer between the conductive material and the substrate 117. The dummy TSVs 111 may also comprise the conductive material and the thin barrier layer between the conductive material and the dielectric layers of the interconnect structure 119. The dummy TSVs 111 may be uniformly distributed within the substrate 117 and the interconnect structure 119 along the edge regions of the semiconductor die 150, while the TSVs 112 are disposed within the substrate 117 in a central region of the semiconductor die 150. In this way, as seen in FIGS. 1A, 1B, 4A, and 4B the dummy TSVs 111 are disposed adjacent to the edges (e.g., close to the periphery) of the semiconductor die 150, and are disposed to be around the TSVs 112.

After the formation of the dummy TSVs 111, the first portions of contact pads 125 are formed in one or more dielectric layers of the interconnect structure 119. To form the first portions of the contact pads 125, first openings are first formed in the one or more dielectric layers of the interconnect structure 119 using acceptable photolithography and etching techniques. The first openings expose surfaces of the dummy TSVs 111. A conductive material may then be formed in the first openings using a deposition process such as sputtering, evaporation, CVD, plasma-enhanced chemical vapor deposition (PECVD), a plating process, an electroless plating process, or the like. The conductive material may comprise copper, aluminum, or another conductive material. A planarization process is then performed to remove excess portions of the conductive material, and the remaining conductive material in the first openings forms the first portions of the contact pads 125. In this way, the first portion of each contact pad 125 is embedded in the one or more dielectric layers of the interconnect structure 119.

After the dummy TSVs 111 and the first portions of the contact pads 125 have been formed, the dielectric layer 120, the one or more contact pads 124, the second portions of the contact pads 125, and the BPVs 130 are formed as described previously in FIGS. 1A, 1B, and 2. Each dummy TSV 111 may be in physical contact with a respective contact pad 125. Furthermore, after the dielectric layer 120, the one or more contact pads 124, the second portions of the contact pads 125, and the BPVs 130 are formed, the bonding layer 121 and the bonding pads 123 are formed over the dielectric layer 120 and the BPVs 130 as described previously in FIGS. 1A, 1B, and 2. In an embodiment, each dummy TSV 111 may be electrically connected to a respective contact pad 125, a respective first BPV 130, and a respective first bonding pad 123. In addition, each dummy TSV is electrically isolated from the seal ring 128. In an embodiment, the first bonding pads 123 and the first BPVs 130 are optional and may not be formed. Each dummy TSV 111 is in physical contact with and overlaps a respective contact pad 125 when the semiconductor die 150 is oriented in such a way that the substrate 117 is disposed to be vertically above the interconnect structure 119.

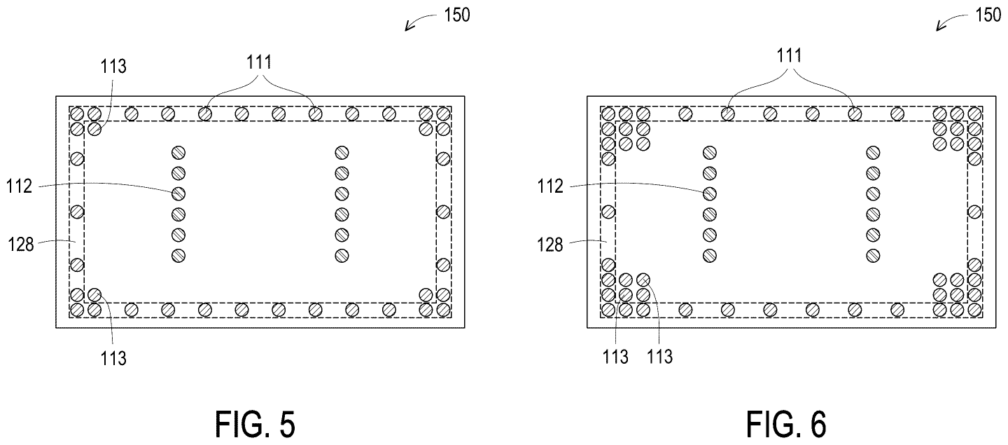

FIGS. 5 and 6 illustrate top-down views of the semiconductor die 150, in accordance with alternative embodiments. Unless specified otherwise, like reference numerals in this embodiment (and subsequently discussed embodiments) represent like components in the embodiment shown in FIGS. 1A through 4B formed by like processes. Accordingly, the process steps and applicable materials may not be repeated herein.

The TSVs 112 may extend through the substrate 117, and may be disposed in a central region (e.g., as shown in FIGS. 5 and 6) of the semiconductor die 150. In an embodiment, the TSVs 112 may also extend partially or completely through the interconnect structure 119 to electrically connect to the metallization patterns 126. In addition, the semiconductor die 150 comprises the dummy TSVs 111 which extend through the substrate 117. The dummy TSVs 111 may also extend partially or completely through the interconnect structure 119. The dummy TSVs 111 may be distributed within the semiconductor die 150 along the edge regions of the semiconductor die 150. In an embodiment, the dummy TSVs 111 may be arranged along the seal ring 128 (shown in ghost in FIGS. 5 and 6), such that each dummy TSV 111 overlaps and is in physical contact with the seal ring 128. Clusters of dummy TSVs 111 may be disposed to overlap corner regions of the seal ring 128, such that a concentration of the dummy TSVs 111 is higher along the corner regions of the seal ring 128 than other regions of the seal ring 128. In addition, the semiconductor die 150 may also comprise dummy TSVs 113, which are formed using similar processes and similar materials as the dummy TSVs 111. The dummy TSVs 113 may be disposed adjacent to corner regions of the seal ring 128 such that the dummy TSVs 113 are disposed within an inner perimeter of the seal ring 128, when seen in a top-down view. The dummy TSVs 113 are therefore not in physical contact with the seal ring 128, and also do not overlap the seal ring 128. In an embodiment, a single dummy TSV 113 is disposed adjacent to each corner region of the seal ring 128, as shown in FIG. 5. In an embodiment, a cluster of dummy TSVs 113 (e.g., more than one dummy TSV 113) is disposed adjacent to each respective corner region of the seal ring 128, as shown in FIG. 6.

In FIG. 7, a semiconductor wafer 200 is bonded to the semiconductor die 150. The wafer 200 may also be subsequently referred to as a bottom die. The materials and formation processes of the features in the wafer 200 may be found by referring to the like features in the semiconductor die 150, with the like features in the semiconductor die 150 starting with number “1,” which features correspond to the features in the wafer 200 and having reference numerals starting with number “2.” For example, the wafer 200 may include a substrate 217 having devices (e.g., transistors, capacitors, diodes, resistors, or the like) formed thereon and an interconnect structure 219. The interconnect structure 219 electrically connects the devices on the substrate 217 to form one or more integrated circuits. The interconnect structure 219 includes one or more dielectric layers (for example, one or more interlayer dielectric (ILD) layers, intermetal dielectric (IMD) layers, or the like) and metallization patterns 226 (which may also be referred to as interconnect wirings subsequently) embedded in the one or more dielectric layers. In an embodiment, the interconnect structure 219 may or may not comprise a seal ring (not shown in the FIG. 7), the seal ring being similar to the seal ring 128 described previously in FIGS. 1 through 6.

A dielectric layer 220 is disposed on the interconnect structure 219, a bonding layer 221 is disposed on the dielectric layer 220, and bonding pads 223 are disposed in the bonding layer 221. The side of the wafer 200 comprising the bonding pads 223 and the bonding layer 221 may also be referred to subsequently as the front side of the wafer 200. The side of the wafer 200 comprising an exposed back side surface of the substrate 217 may also be referred to subsequently as the back side of the wafer 200. Bonding pad vias (BPVs) 230 may extend through the dielectric layer 220, and the bonding pads 223 allow connections to be made to the interconnect structure 219 (e.g., the metallization patterns 226) and the devices on the substrate 217 through the BPVs 230. One or more contact pads 224 may also be embedded within the dielectric layer 220 to which external connections are made to the interconnect structure 219, the metallization patterns 226, and the devices in and/or on the substrate 217.

Still referring to FIG. 7, the semiconductor die 150 is bonded to the wafer 200, for example, in a hybrid bonding configuration. The semiconductor die 150 is disposed face down and bonded to the wafer 200, such that the front side of the semiconductor die 150 is bonded to the front side of the wafer 200. The semiconductor die 150 is bonded to the bonding layer 221 on the front side of the wafer 200 and the bonding pads 223 in the bonding layer 221. For example, the bonding layer 121 of the semiconductor die 150 may be directly bonded to the bonding layer 221 of the wafer 200, and bonding pads 123 of the semiconductor die 150 may be directly bonded to the bonding pads 223 of the wafer 200. In an embodiment, the bond between the bonding layer 121 and the bonding layer 221 may be an oxide-to-oxide bond, or the like. The hybrid bonding process further directly bonds the bonding pads 123 of the semiconductor die 150 to the bonding pads 223 of the wafer 200 through direct metal-to-metal bonding. Thus, electrical connection between the semiconductor die 150 and the wafer 200 is provided by the physical connection of the bonding pads 123 to the bonding pads 223.

As an example hybrid bonding process starts with aligning the semiconductor die 150 with the wafer 200, for example, by applying a surface treatment to one or more of the bonding layer 121 or the bonding layer 221. The surface treatment may include a plasma treatment. The plasma treatment may be performed in a vacuum environment. After the plasma treatment, the surface treatment may further include a cleaning process (e.g., a rinse with deionized water, or the like) that may be applied to one or more of the bonding layer 121 or the bonding layer 221. The hybrid bonding process may then proceed to aligning the bonding pads 123 to the bonding pads 223. Next, the semiconductor die 150 is put in contact with the wafer 200 which may be at room temperature (e.g., between about 21° C. and about 25° C.). The hybrid bonding process continues with performing an anneal, for example, at a temperature between about 150° C. and about 400° C. for a duration between about 0.5 hours and about 3 hours, so that the metal in bonding pads 123 (e.g., copper) and the metal of the bonding pads 223 (e.g., copper) inter-diffuses to each other, and hence the direct metal-to-metal bonding is formed.

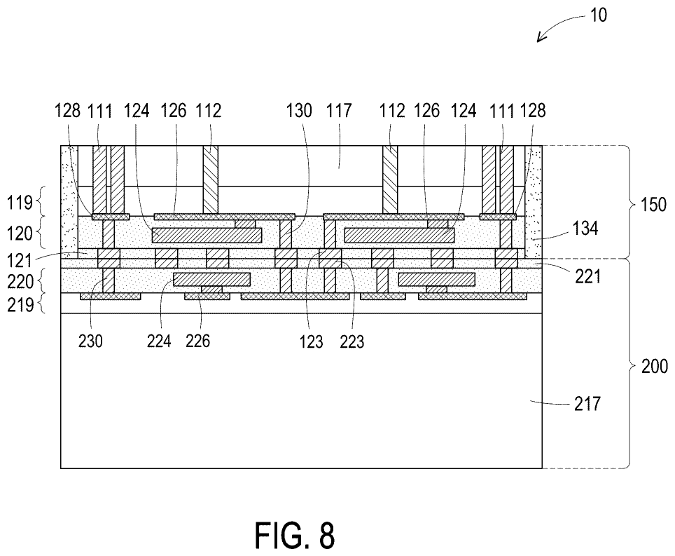

In FIG. 8, an insulating material 134 (also referred to as a gapfill material or an encapsulant) is formed over the semiconductor die 150 and the wafer 200, in order to encapsulate the semiconductor die 150. In accordance with some embodiments, the insulating material 134 may be an oxide (e.g., silicon dioxide), or the like. The insulating material 134 may be formed by spin-coating, high-density CVD, or the like. After the formation of the insulating material 134, a planarization process may be performed to remove excess material of the insulating material 134 over the semiconductor die 150, so as to expose top surfaces of the substrate 117, the dummy TSVs 111, and the TSVs 112. After the planarization process, the top surfaces of the substrate 117, the dummy TSVs 111, and the TSVs 112 may be level (within process variations) with top surfaces of the insulating material 134. The planarization process may be a grinding process, a chemical mechanical polish (CMP) process, or the like. However, any suitable planarization process may be utilized.

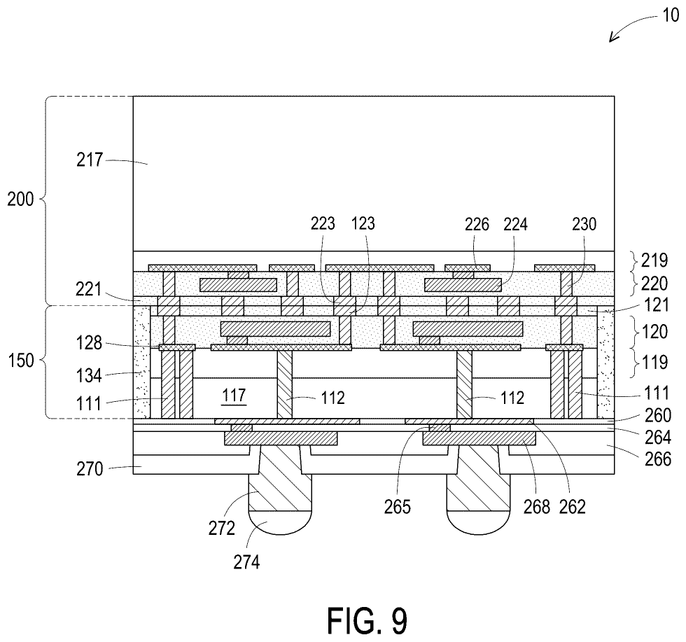

In FIG. 9, the structure shown in FIG. 8 is shown flipped over, with a dielectric layer 260 being formed on a bottom surface of the integrated chip package 10, such as on the exposed surfaces of the substrate 117, the dummy TSVs 111, and the TSVs 112. The dielectric layer 260 is also formed on the insulating material 134. In an embodiment, the dielectric layer 260 may comprise silicon oxide, silicon nitride, silicon oxynitride, a polymer, or the like and be deposited by PVD, CVD, ALD, or the like. The dielectric layer 260 is then patterned. The patterning forms openings that expose portions of the substrate 117 and the TSVs 112 of the semiconductor die 150. The patterning may be by acceptable photolithography and etching techniques.

A metallization pattern 262 is then formed. The metallization pattern 262 includes conductive elements extending along the major surface of the dielectric layer 260 and extending through the dielectric layer 260 to physically and electrically couple to the TSVs 112 of the semiconductor die 150. As an example to form the metallization pattern 262, a seed layer is formed over the dielectric layer 260 and in the openings extending through the dielectric layer 260. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the metallization pattern 262. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. The combination of the conductive material and underlying portions of the seed layer form the metallization pattern 262. The photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching.

After the formation of the dielectric layer 260 and the metallization pattern 262, a dielectric layer 264 is formed on the dielectric layer 260 and the metallization pattern 262. The dielectric layer 264 may be formed using similar processes and similar materials as those used during the formation of the dielectric layer 260. A metallization pattern 265 is then formed in the dielectric layer 264. The metallization pattern 265 may be formed using similar processes and similar materials as those used during the formation of the metallization pattern 262.

After the formation of the dielectric layer 264 and the metallization pattern 265, a dielectric layer 266 is formed on the dielectric layer 264 and the metallization pattern 265. The dielectric layer 266 may comprise a polymer, such as polybenzoxazole (PBO), polyimide (PI)), or the like. In an embodiment, the dielectric layer 266 may comprise silicon oxide, silicon nitride, silicon oxynitride, or the like. The dielectric layer 266 may be formed using spin coating, lamination, PVD, CVD, ALD, or the like. Contact pads 268 may be embedded within the dielectric layer 266. To form the contact pads 268, openings for the contact pads 268 are first formed in a first sub-layer of the dielectric layer 266 using acceptable photolithography and etching techniques. A conductive material may then be formed in the openings using a deposition process such as sputtering, evaporation, CVD, plasma-enhanced chemical vapor deposition (PECVD), a plating process, an electroless plating process, a combination thereof, or the like. The conductive material may comprise copper, aluminum, or another conductive material. A planarization process is then performed to remove excess conductive material from surfaces of the first sub-layer of the dielectric layer 266. A second sub-layer of the dielectric layer 266 is then formed on the first sub-layer of the dielectric layer 266 and the contact pads 268. The contact pads 268 may be electrically connected to the TSVs 112 through the metallization pattern 265 and the metallization pattern 262.

After the formation of the contact pads 268 and the dielectric layer 266, first openings are formed in the dielectric layer 266 to expose surfaces of the contact pads 268. The first openings may be formed using acceptable etching techniques. After the formation of the first openings, dielectric layer 270 is formed on the dielectric layer 266 and in the first openings. For example the dielectric layer 270 may be formed on sidewalls in the first openings and on the exposed surfaces of the contact pads 268 within the first openings. The dielectric layer 270 may comprise a polymer, such as polyimide (PI)), or the like. The dielectric layer 266 may be formed using spin coating, lamination, or the like.

After the formation of the dielectric layer 270, lateral portions of the dielectric layer 270 within the first openings are removed so as to re-expose the contact pads 268. The lateral portions of the dielectric layer 270 may be removed using acceptable etching techniques. After the removal of the lateral portions of the dielectric layer 270, remaining portions of the dielectric layer 270 remain disposed on sidewalls of each of the first openings.

Referring further to FIG. 9, under bump metallurgies (UBMs) 272 are formed in the first openings for external connection to the contact pads 268. The UBMs 272 have bump portions on and extending along the major surface of the dielectric layer 270, and have via portions extending through the dielectric layer 270 and the dielectric layer 266 to physically and electrically couple the contact pads 268. As a result, the UBMs 272 are electrically coupled to the TSVs 112, and the metallization patterns 126 of the semiconductor die 150. In addition, the UBMs 272 are also electrically connected to the metallization patterns 226 and the contact pads 224 of the wafer 200, through the BPVs 130, the BPVs 230, the bonding pads 123, and the bonding pads 223. The UBMs 272 may be formed of the same material as the metallization patterns 126 and 226.

After the formation of the UBMs 272, conductive connectors 274 are formed on the UBMs 272. The conductive connectors 274 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 274 may include a conductive material such as solder, copper, aluminum, gold, nickel, silver, palladium, tin, the like, or a combination thereof. In some embodiments, the conductive connectors 274 are formed by initially forming a layer of solder through evaporation, electroplating, printing, solder transfer, ball placement, or the like. Once a layer of solder has been formed on the structure, a reflow may be performed in order to shape the material into the desired bump shapes. The conductive connectors 274 may be used to couple and electrically connect the integrated chip package 10 to other external devices, such as for example, a package substrate, or the like.

FIGS. 10A through 21 illustrate cross-sectional views of intermediate steps during a process for forming an integrated chip package 20, in accordance with alternate embodiments. Unless specified otherwise, like reference numerals in this embodiment (and subsequently discussed embodiments) represent like components in the embodiment shown in FIGS. 1A through 9 formed by like processes. Accordingly, the process steps and applicable materials may not be repeated herein.

In FIGS. 10A and 10B, a semiconductor die 250 is illustrated. FIG. 10A illustrates a cross-sectional view of the semiconductor die 250. FIG. 10B illustrates a top-down view of the semiconductor die 250. The semiconductor die 250 may be similar to the semiconductor die 150 described previously in FIGS. 1A through 9, except that the semiconductor die 250 does not comprise the functional TSVs 112 extending through the substrate 117 of the semiconductor die 250. The dummy TSVs 111 may be disposed adjacent to the edges (e.g., close to the periphery) of the semiconductor die 250 and may overlap and be in physical contact with the seal ring 128 as described previously in FIGS. 1A through 9. However, as shown in FIG. 10B, no TSVs 112 are disposed within a central region of the semiconductor die 250.

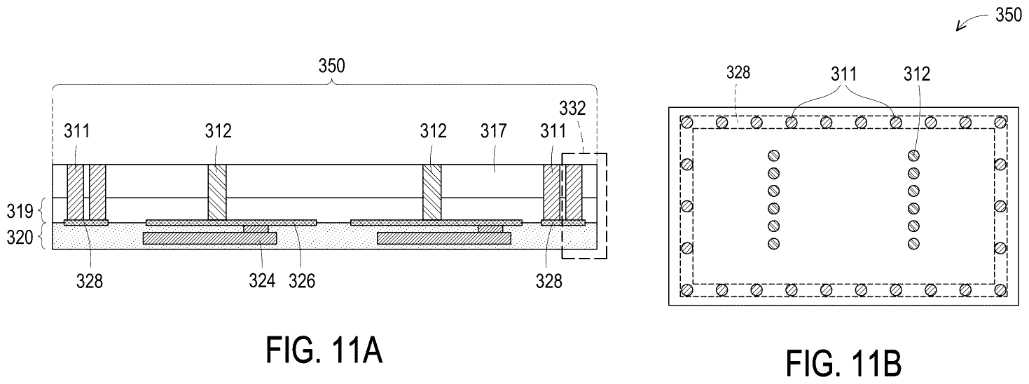

FIGS. 11A and 11B illustrate a semiconductor die 350. The semiconductor die 350 may also be subsequently referred to as a bottom die. The materials and formation processes of the features in the semiconductor die 350 may be found by referring to the like features in the semiconductor die 150, with the like features in the semiconductor die 150 starting with number “1,” which features correspond to the features in the semiconductor die 350 and having reference numerals starting with number “3.” For example, the semiconductor die 350 may include a substrate 317 having devices (e.g., transistors, capacitors, diodes, resistors, or the like) formed thereon and an interconnect structure 319 on the substrate 317. The interconnect structure 319 electrically connects the devices on the substrate 317 to form one or more integrated circuits. The interconnect structure 319 includes one or more dielectric layers (for example, one or more interlayer dielectric (ILD) layers, intermetal dielectric (IMD) layers, or the like) and metallization patterns 326 (which may also be referred to as interconnect wirings subsequently) embedded in the one or more dielectric layers. In an embodiment, the interconnect structure 319 may comprise a seal ring 328, (shown in ghost in FIG. 11B) that is disposed within the interconnect structure 319 and adjacent to the edges (e.g., close to the periphery) of the semiconductor die 350, and that surrounds the metallization patterns 326 within the interconnect structure 319.

The semiconductor die 350 further comprises functional TSVs 312 which may be electrically connected to the metallization patterns 326 in the interconnect structure 319. The TSVs 312 may extend through the substrate 317, and may be disposed in a central region (e.g., as shown in FIG. 11B) of the semiconductor die 350. In an embodiment, the TSVs 312 may also extend partially or completely through the interconnect structure 319 to electrically connect to the metallization patterns 326. In addition, the semiconductor die 350 comprises dummy TSVs 311 which extend through the substrate 317. The dummy TSVs 311 may also extend partially or completely through the interconnect structure 319. The dummy TSVs 311 may be uniformly distributed within the semiconductor die 350 along the edge regions of the semiconductor die 350. In an embodiment, the dummy TSVs 311 may be arranged along the seal ring 328 (shown in ghost in FIG. 11B), such that each dummy TSV 311 overlaps the seal ring 328. For example, pairs of dummy TSVs 311 (e.g., as shown in FIG. 11A) may be uniformly distributed (e.g., disposed at regular intervals) above and along the seal ring 328, wherein bottom surfaces of the dummy TSVs 311 are in physical contact with the seal ring 328. In other embodiments, single ones of the dummy TSVs 311 are uniformly distributed (e.g., disposed at regular intervals) above and along the seal ring 328, wherein bottom surfaces of the dummy TSVs 311 are in physical contact with the seal ring 328. The dummy TSVs 311 may be disposed adjacent to the edges (e.g., close to the periphery) of the semiconductor die 350, wherein the dummy TSVs 311 are disposed to be around the TSVs 312, the TSVs 312 being disposed within a central region of the semiconductor die 350. The dummy TSVs 311 and the TSVs 312 may comprise copper, tungsten, aluminum, silver, gold, a combination thereof, and/or the like. The TSVs 312 provide electrical connection from a back side of the substrate 317 to a front side of the substrate 317.

A dielectric layer 320 is disposed on the interconnect structure 319. The side of the semiconductor die 350 comprising the dielectric layer 320 may also be referred to subsequently as the front side of the semiconductor die 350. The side of the semiconductor die 350 comprising an exposed back side surface of the substrate 317 may also be referred to subsequently as the back side of the semiconductor die 350. One or more contact pads 324 may also be embedded within the dielectric layer 320 to which external connections are made to the interconnect structure 319, the metallization patterns 326, and the devices in and/or on the substrate 317.

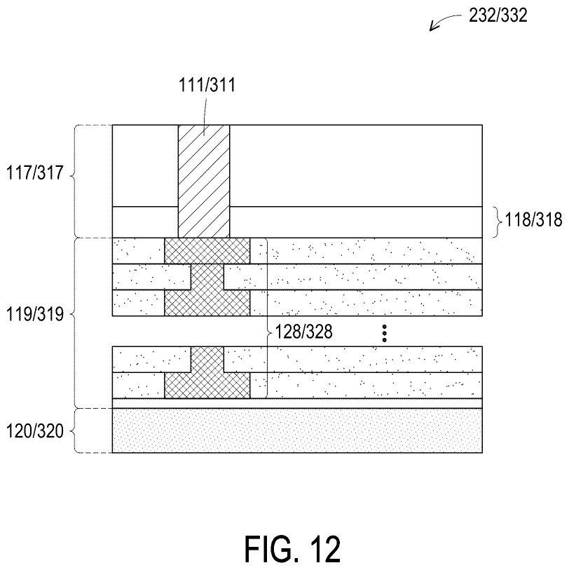

FIG. 12 illustrates an edge region 232 of the semiconductor die 250 shown in FIG. 10A, in accordance with an embodiment. FIG. 12 also illustrates an edge region 332 of the semiconductor die 350 shown in FIG. 11A, in accordance with an embodiment. Unless specified otherwise, like reference numerals of the semiconductor die 250 in this embodiment (and subsequently discussed embodiments) represent like components in the embodiment shown in FIG. 2 (e.g., describing the formation of the semiconductor die 150) formed by like processes. Accordingly, the process steps and applicable materials may not be repeated herein. Furthermore, unless specified otherwise, the materials and formation processes of the features in the semiconductor die 350 shown in this embodiment (and subsequently discussed embodiments) may be found by referring to the like features in the semiconductor die 150 of FIG. 2, with the like features in the semiconductor die 150 starting with number “1,” which features correspond to the features in the semiconductor die 350 and having reference numerals starting with number “3.”

As shown in FIG. 10A and the corresponding edge region 232 of FIG. 12, the process of forming the semiconductor die 250 differs from the process of forming the semiconductor die 150 (described previously in FIG. 2) in that when forming the semiconductor die 250, the TSVs 112 are not formed to extend through the substrate 117. Instead only the dummy TSVs 111 are formed to extend entirely through the substrate 117 (e.g., including the FEOL layer 118). Further, the contact pads 125 and the first BPVs 130 are not formed in the dielectric layer 120. However, the second BPVs 130 are formed to be in physical contact with surfaces (e.g., surfaces of contact pads) of the metallization patterns 126 as described previously in FIGS. 1A through 2.

Furthermore, as shown in FIG. 11A and the corresponding edge region 332 of FIG. 12, the process of forming the semiconductor die 350 differs from the process of forming the semiconductor die 150 (described previously in FIG. 2) in that when forming the semiconductor die 350, the contact pads 125 and the BPVs 130 (shown previously in FIGS. 1A through 2) are not formed in the dielectric layer 320.

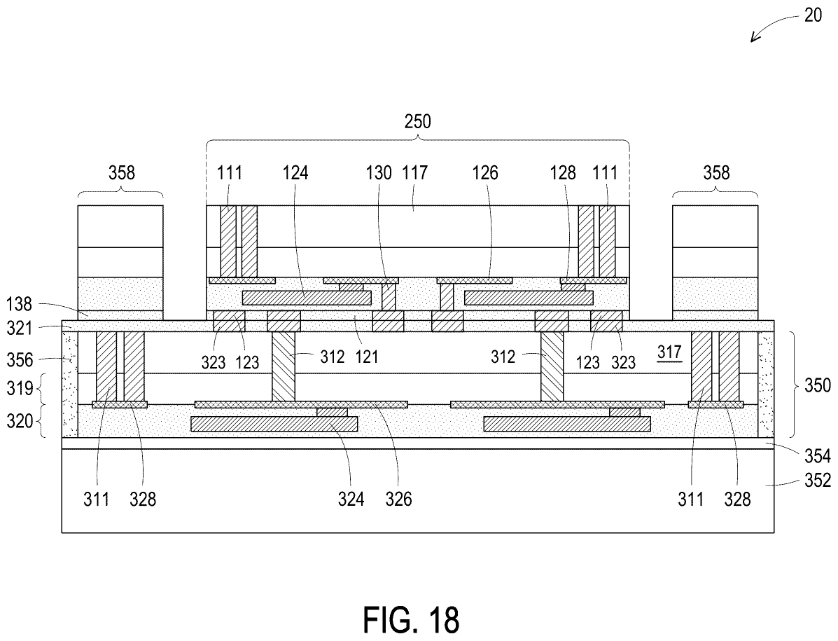

Advantages may be achieved as a result of forming the semiconductor die 250 that comprises the dummy TSVs 111 that are distributed within the semiconductor die 250 along the edge regions of the semiconductor die 250. The dummy TSVs 111 may be arranged along the seal ring 128, such that each dummy TSV 111 overlaps and is in physical contact with the seal ring 128. The dummy TSVs 111 may be disposed at regular intervals (e.g., uniformly distributed) or irregular intervals (e.g., non-uniformly distributed) above and along the seal ring 128. In addition, the semiconductor die 350 is formed comprising the dummy TSVs 311 that are distributed within the semiconductor die 350 along the edge regions of the semiconductor die 350. The dummy TSVs 311 may be arranged along the seal ring 328, such that each dummy TSV 311 overlaps and is in physical contact with the seal ring 328. The dummy TSVs 311 may be disposed at regular intervals (e.g., uniformly distributed) or irregular intervals (e.g., non-uniformly distributed) above and along the seal ring 328, wherein the dummy TSVs 311 are disposed to be around the TSVs 312, the TSVs 312 being disposed within a central region of the semiconductor die 350. These advantages include increasing a metal density of the edge regions of the semiconductor die 250, and reducing a difference between the metal density of the edge regions of the semiconductor die 250 and a metal density of a central region of the semiconductor die 250. This allows for the reducing of a difference between a co-efficient of thermal expansion (CTE) of the edge regions of the semiconductor die 250 and a co-efficient of thermal expansion (CTE) of the central region of the semiconductor die 250. In addition, a metal density of the edge regions of the semiconductor die 350 is increased, and as a result, a difference between the metal density of the edge regions of the semiconductor die 350 and a metal density of a central region of the semiconductor die 350 is reduced. This allows for the reducing of a difference between a co-efficient of thermal expansion (CTE) of the edge regions of the semiconductor die 350 and a co-efficient of thermal expansion (CTE) of the central region of the semiconductor die 350. This results in a reduction of thermal stresses that are generated within each of the semiconductor die 250 and the semiconductor die 350, and further results in a reduced risk of warping of the semiconductor die 250 and the semiconductor die 350. This ensures that bottom surfaces of the edge regions of the semiconductor die 250 and top surfaces of edge regions of the semiconductor die 350 do not curve (also referred to as tilt) away from each other after the semiconductor die 250 is bonded to the semiconductor die 350 (shown subsequently in FIG. 18), and allows adequate physical contact between the bonding pads 123 on the edge regions of the semiconductor die 250, and respective bonding pads 323 on the semiconductor die 350. In this way, bonding between the semiconductor die 250 and the semiconductor die 350 is improved, and device reliability is enhanced. In addition, preventing the edge regions of the semiconductor die 250 from tilting upwards away from top surfaces of the semiconductor die 350 reduces a risk of forming a gap between the semiconductor die 250 and the semiconductor die 350. As a result, a risk of chemical damage or moisture damage to the exposed surfaces of the semiconductor die 250 and the semiconductor die 350 within the gap during subsequently performed processing steps is reduced.

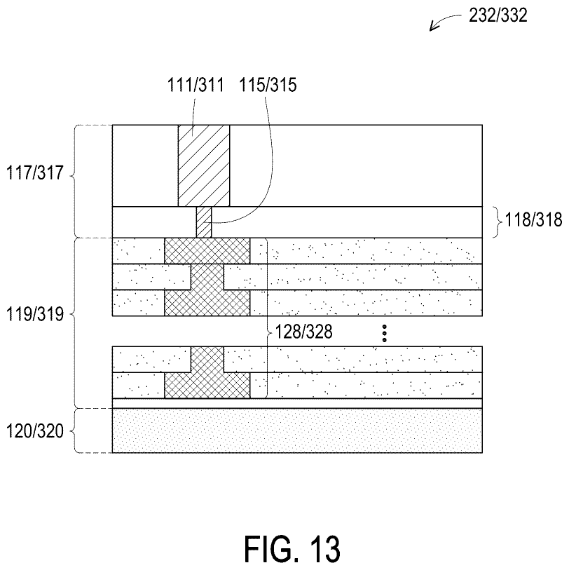

FIG. 13 illustrates the edge region 232 of the semiconductor die 250 shown in FIG. 10A, in accordance with an alternate embodiment. FIG. 13 also illustrates the edge region 332 of the semiconductor die 350 shown in FIG. 11A, in accordance with an alternate embodiment. Unless specified otherwise, like reference numerals of the semiconductor die 250 in this embodiment (and subsequently discussed embodiments) represent like components in the embodiment shown in FIG. 12 (e.g., describing the formation of the semiconductor die 250) formed by like processes. Accordingly, the process steps and applicable materials may not be repeated herein. Additionally, unless specified otherwise, like reference numerals of the semiconductor die 350 in this embodiment (and subsequently discussed embodiments) represent like components in the embodiment shown in FIG. 12 (e.g., describing the formation of the semiconductor die 350) formed by like processes. Accordingly, the process steps and applicable materials may not be repeated herein.

As shown in FIG. 10A and the corresponding edge region 232 of FIG. 13, the process of forming the semiconductor die 250 shown in the embodiment of FIG. 13 differs from the process of forming the semiconductor die 250 described previously in FIG. 12 in that when forming the semiconductor die 250 shown in the embodiment of FIG. 13, the dummy TSVs 111 are formed first to extend partially through the substrate 117, prior to forming the FEOL layer 118 in and/or on the front side of the substrate 117. In an embodiment, each dummy TSV 111 may be electrically connected to the seal ring 128 through the conductive plug 115 that is formed in the FEOL layer 118. The formation of the dummy TSVs 111, the interconnect structure 119, the dielectric layer 120, and the second BPVs 130 of the semiconductor die 250 is done using similar materials and similar processes as were described for the formation of the dummy TSVs 111, the interconnect structure 119, the dielectric layer 120, and the second BPVs 130 of the semiconductor die 150 in FIG. 3, respectively.

Furthermore, as shown in FIG. 11A and the corresponding edge region 332 of FIG. 13, the process of forming the semiconductor die 350 shown in the embodiment of FIG. 13 differs from the process of forming the semiconductor die 350 described previously in FIG. 12 in that when forming the semiconductor die 350 shown in the embodiment of FIG. 13, the dummy TSVs 311 are formed first to extend partially through the substrate 317, prior to forming the FEOL layer 318 in and/or on the front side of the substrate 317. The TSVs 312 may be then formed after forming the FEOL layer 318 in and/or on the front side of the substrate 317. In an embodiment, each dummy TSV 311 may be electrically connected to the seal ring 328 through the conductive plug 315 that is formed in the FEOL layer 318. The formation of the dummy TSVs 311, the TSVs 312, the interconnect structure 319, and the dielectric layer 320 of the semiconductor die 250 is done using similar materials and similar processes as were described for the formation of the dummy TSVs 111, the TSVs 112, the interconnect structure 119, and the dielectric layer 320 of the semiconductor die 150 in FIG. 3, respectively.

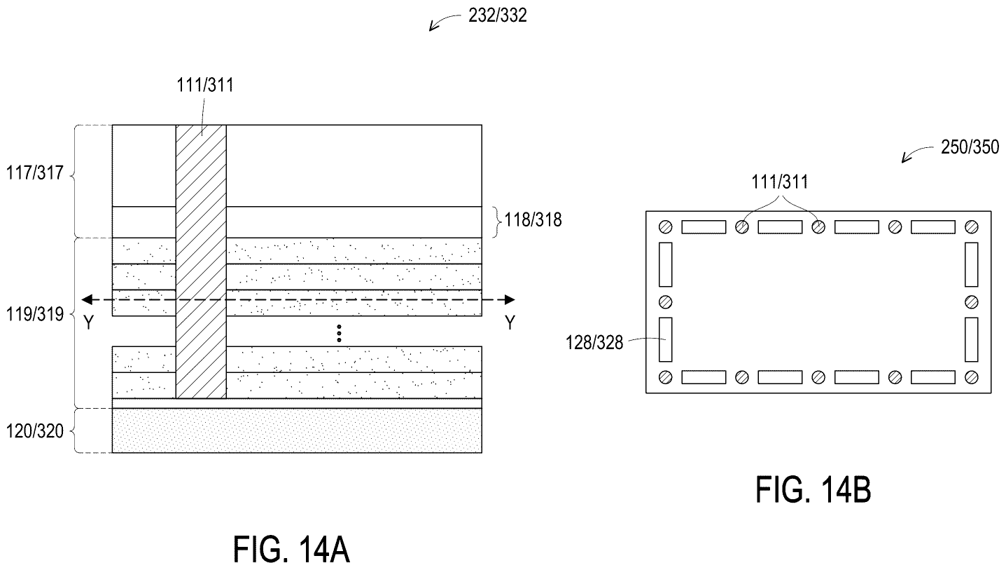

FIG. 14A illustrates the edge region 232 of the semiconductor die 250 shown in FIG. 10A, in accordance with an alternative embodiment. FIG. 14A also illustrates the edge region 332 of the semiconductor die 350 shown in FIG. 11A, in accordance with an alternative embodiment. FIG. 14B illustrates a top-down view of the semiconductor die 150/350 along a cross-section Y-Y shown in FIG. 14A. Unless specified otherwise, like reference numerals of the semiconductor die 250 in this embodiment (and subsequently discussed embodiments) represent like components in the embodiment shown in FIG. 12 (e.g., describing the formation of the semiconductor die 250) formed by like processes. Accordingly, the process steps and applicable materials may not be repeated herein. Additionally, unless specified otherwise, like reference numerals of the semiconductor die 350 in this embodiment (and subsequently discussed embodiments) represent like components in the embodiment shown in FIG. 12 (e.g., describing the formation of the semiconductor die 350) formed by like processes. Accordingly, the process steps and applicable materials may not be repeated herein.

As shown in FIG. 10A and the corresponding edge region 232 of FIG. 14A, the process of forming the semiconductor die 250 shown in the embodiment of FIG. 14A differs from the process of forming the semiconductor die 250 described previously in FIG. 12 in that when forming the semiconductor die 250 shown in the embodiment of FIG. 14A, the dummy TSVs 111 are formed after the formation of the FEOL layer 118 in and/or on the front side of the substrate 117, and the interconnect structure 119 (e.g., including the seal ring 128 and the metallization patterns 126). The FEOL layer 118 is first formed in and/or on the front side of the substrate 117. After the FEOL layer 118 has been formed in and/or on the front side of the substrate 117, the interconnect structure 119 (including the seal ring 128 and the metallization patterns 126) is then formed. The seal ring 128 may be formed so as to have intermittent gaps in its structure as shown in FIG. 14B. Each gap in the seal ring 128 structure is disposed between adjacent portions of the seal ring 128, and the gaps are filled with a dielectric material of the one or more dielectric layers of the interconnect structure 119.

The dummy TSVs 111 are then formed to extend through the substrate 117 (including the FEOL layer 118), and partially through the interconnect structure 119. Each dummy TSV 111 may extend through a respective gap (e.g., through the dielectric material of the one or more dielectric layers of the interconnect structure 119 disposed within the respective gap) between adjacent portions of the seal ring 128 as shown in FIG. 14B. The formation of the dummy TSVs 111, the interconnect structure 119 (e.g., including the metallization pattern 126 and the seal ring 128), the dielectric layer 120, and the second BPVs 130 of the semiconductor die 250 is done using similar materials and similar processes as were described for the formation of the dummy TSVs 111, the interconnect structure 119 (e.g., including the metallization patterns 126 and the seal ring 128), the dielectric layer 120, and the second BPVs 130 of the semiconductor die 150 in FIGS. 4A and 4B, respectively.

Furthermore, as shown in FIG. 11A and the corresponding edge region 332 of FIG. 14A, the process of forming the semiconductor die 350 shown in the embodiment of FIG. 14A differs from the process of forming the semiconductor die 350 described previously in FIG. 12 in that when forming the semiconductor die 350 shown in the embodiment of FIG. 14A, the dummy TSVs 311 are formed after the formation of the FEOL layer 318 in and/or on the front side of the substrate 317, the TSVs 312, and the interconnect structure 319 (e.g., including the seal ring 328 and the metallization patterns 326). The FEOL layer 318 is first formed in and/or on the front side of the substrate 317. After the FEOL layer 318 has been formed in and/or on the front side of the substrate 317, the TSVs 312 are then formed using similar materials and similar processes as were described previously for the TSVs 112 in FIGS. 1A, 1B, and 2. After the TSVs 312 are formed, the interconnect structure 319 (including the seal ring 328 and the metallization patterns 326) is then formed. The seal ring 328 may be formed so as to have intermittent gaps in its structure as shown in FIG. 14B. Each gap in the seal ring 328 structure is disposed between adjacent portions of the seal ring 328, and the gaps are filled with a dielectric material of the one or more dielectric layers of the interconnect structure 319.

The dummy TSVs 311 are then formed to extend through the substrate 317 (including the FEOL layer 318), and partially through the interconnect structure 319. Each dummy TSV 311 may extend through a respective gap (e.g., through the dielectric material of the one or more dielectric layers of the interconnect structure 319 disposed within the respective gap) between adjacent portions of the seal ring 328 as shown in FIG. 14B. The formation of the dummy TSVs 311, the interconnect structure 319 (e.g., including the metallization pattern 326 and the seal ring 328), and the dielectric layer 320 of the semiconductor die 350 is done using similar materials and similar processes as were described for the formation of the dummy TSVs 111, the interconnect structure 119 (e.g., including the metallization patterns 126 and the seal ring 128), and the dielectric layer 120 of the semiconductor die 150 in FIGS. 4A and 4B, respectively.

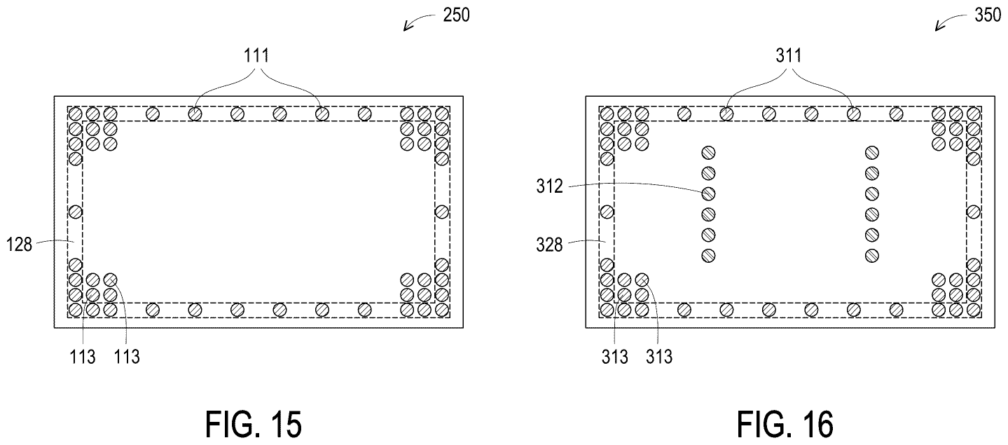

FIG. 15 illustrates a top-down view of the semiconductor die 250 shown previously in FIGS. 10A and 10B, in accordance with alternative embodiments. Unless specified otherwise, like reference numerals in this embodiment (and subsequently discussed embodiments) represent like components in the embodiment shown in FIGS. 10A and 10B formed by like processes. Accordingly, the process steps and applicable materials may not be repeated herein.

The semiconductor die 250 comprises the dummy TSVs 111 which extend through the substrate 117. The dummy TSVs 111 may also extend partially or completely through the interconnect structure 119. The dummy TSVs 111 may be distributed within the semiconductor die 250 along the edge regions of the semiconductor die 250. In an embodiment, the dummy TSVs 111 may be arranged along the seal ring 128 (shown in ghost in FIG. 15), such that each dummy TSV 111 overlaps and is in physical contact with the seal ring 128. Clusters of dummy TSVs 111 may be disposed to overlap corner regions of the seal ring 128, such that a concentration of the dummy TSVs 111 is higher along the corner regions of the seal ring 128 than other regions of the seal ring 128. In addition, the semiconductor die 250 may also comprise dummy TSVs 113, which are formed using similar processes and similar materials as the dummy TSVs 111. The dummy TSVs 113 may be disposed adjacent to corner regions of the seal ring 128 such that the dummy TSVs 113 are disposed within an inner perimeter of the seal ring 128, when seen in a top-down view. The dummy TSVs 113 are therefore not in physical contact with the seal ring 128, and also do not overlap the seal ring 128. In an embodiment, a single dummy TSV 113 is disposed adjacent to each corner region of the seal ring 128. In an embodiment, a cluster of dummy TSVs 113 (e.g., more than one dummy TSV 113) is disposed adjacent to each respective corner region of the seal ring 128, as shown in FIG. 15.

FIG. 16 illustrates a top-down view of the semiconductor die 350 shown previously in FIGS. 11A and 11B, in accordance with alternative embodiments. Unless specified otherwise, like reference numerals in this embodiment (and subsequently discussed embodiments) represent like components in the embodiment shown in FIGS. 11A and 11B formed by like processes. Accordingly, the process steps and applicable materials may not be repeated herein.

The TSVs 312 may extend through the substrate 317, and may be disposed in a central region (e.g., as shown in FIG. 16) of the semiconductor die 350. In an embodiment, the TSVs 312 may also extend partially or completely through the interconnect structure 319 to electrically connect to the metallization patterns 326. In addition, the semiconductor die 350 comprises the dummy TSVs 311 which extend through the substrate 317. The dummy TSVs 311 may also extend partially or completely through the interconnect structure 319. The dummy TSVs 311 may be distributed within the semiconductor die 350 along the edge regions of the semiconductor die 350. In an embodiment, the dummy TSVs 311 may be arranged along the seal ring 328 (shown in ghost in FIG. 16), such that each dummy TSV 311 overlaps and is in physical contact with the seal ring 328. Clusters of dummy TSVs 311 may be disposed to overlap corner regions of the seal ring 328, such that a concentration of the dummy TSVs 311 is higher along the corner regions of the seal ring 328 than other regions of the seal ring 328. In addition, the semiconductor die 350 may also comprise dummy TSVs 313, which are formed using similar processes and similar materials as the dummy TSVs 311. The dummy TSVs 313 may be disposed adjacent to corner regions of the seal ring 328 such that the dummy TSVs 313 are disposed within an inner perimeter of the seal ring 328, when seen in a top-down view. The dummy TSVs 313 are therefore not in physical contact with the seal ring 328, and also do not overlap the seal ring 328. In an embodiment, a single dummy TSV 313 is disposed adjacent to each corner region of the seal ring 328. In an embodiment, a cluster of dummy TSVs 313 (e.g., more than one dummy TSV 313) is disposed adjacent to each respective corner region of the seal ring 328, as shown in FIG. 16. The dummy TSVs 311 and the dummy TSVs 313 are disposed around the TSVs 312 that may be disposed within a central region of the semiconductor die 350

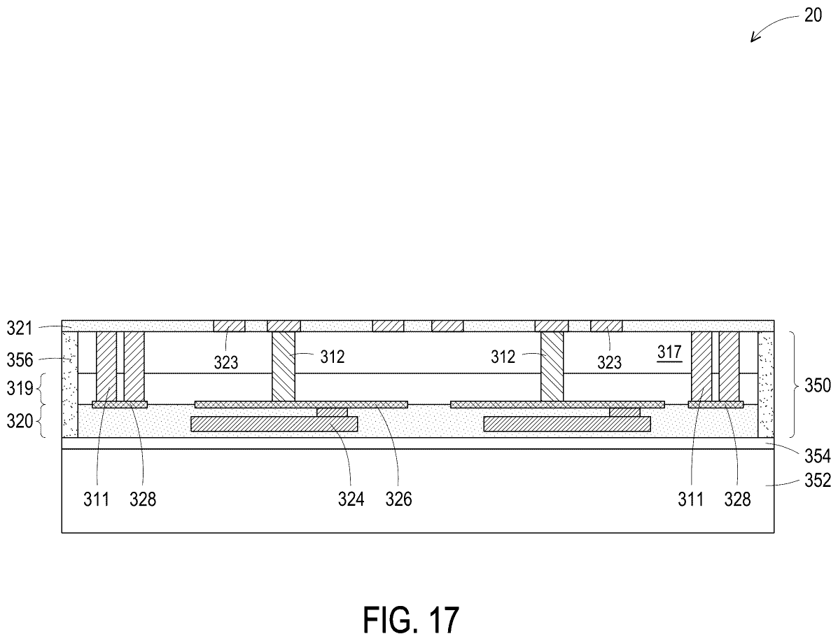

In FIG. 17, a carrier substrate 352 is bonded to the front side (e.g., a surface of the dielectric layer 320) of the semiconductor die 350. The semiconductor die 350 may also be referred to subsequently as a bottom die. The carrier substrate 352 may include a bulk substrate (e.g., a semiconductor substrate) or a wafer, and may be formed of a material such as silicon, ceramic, glass, or the like. The carrier substrate 352 is bonded to the dielectric layer 320 of the semiconductor die 350 using a suitable technique such as fusion bonding, or the like. For example, in various embodiments, the carrier substrate 352 may be bonded to the semiconductor die 350 using a bonding layer 354 on a surface of the carrier substrate 352. In some embodiments, the bonding layer 354 may comprise silicon oxide formed on the surface of the carrier substrate 352 by a deposition process, such as chemical vapor deposition (CVD), physical vapor deposition (PVD), or the like. In other embodiments, the bonding layer 354 may be formed by the thermal oxidation of a silicon surface on the carrier substrate 352. The dielectric layer 320 may comprise silicon oxide, or the like.

Prior to bonding, the bonding layer 354 may be subjected to a surface treatment. The surface treatment may include a plasma treatment. The plasma treatment may be performed in a vacuum environment. After the plasma treatment, the surface treatment may further include a cleaning process (e.g., a rinse with deionized water, or the like) that may be applied to the bonding layer 354. The carrier substrate 352 is then aligned with the semiconductor die 350 and the two are pressed against each other at a temperature that is, for example, between about 21 degrees and about 25 degrees, such that the carrier substrate 352 is in contact and bonded with the semiconductor die 350. The bonding process may be strengthened by a subsequent annealing step. For example, this may be done by heating the semiconductor die 350 and the carrier substrate 352 to a temperature in a range from 140° C. to 500° C.

After the carrier substrate 352 is bonded to the semiconductor die 350, an insulating material 356 (also referred to as an encapsulant) is formed over the semiconductor die 350 and the carrier substrate 352, in order to encapsulate the semiconductor die 350. In accordance with some embodiments, the insulating material 356 may be an oxide (e.g., silicon dioxide), or the like. The insulating material 356 may be formed by spin-coating, high-density CVD, or the like. After the formation of the insulating material 356, a planarization process may be performed to remove excess material of the insulating material 356 over the semiconductor die 350, so as to expose top surfaces of the substrate 317, the dummy TSVs 311, and the TSVs 312. After the planarization process, the top surfaces of the substrate 317, the dummy TSVs 311, and the TSVs 312 may be level (within process variations) with top surfaces of the insulating material 356. The planarization process may be a grinding process, a chemical mechanical polish (CMP) process, or the like. However, any suitable planarization process may be utilized.

After the planarization process, a bonding layer 321 is formed on top surfaces of the semiconductor die 350 (e.g., top surfaces of the substrate 317, the TSVs 312, and the dummy TSVs 311) and the insulating material 356. Bonding pads 323 are embedded in the bonding layer 321, wherein the bonding pads 323 are in physical contact with the TSVs 312, and allow electrical connection to be made to the contact pads 324, the metallization patterns 326 of the interconnect structure 319, and the devices in or on the substrate 317 through the TSVs 312. In an embodiment, the bonding pads 323 may not overlap and be in physical contact with the dummy TSVs 311. The material of the bonding layer 321 may be silicon oxide (SiOₓ, where x>0), silicon nitride (SiNₓ, where x>0), silicon oxynitride (SiOₓN_{y}, where x>0 and y>0), tetraethyl orthosilicate (TEOS), or other suitable dielectric material, and the bonding pads 323 may comprise conductive pads (e.g., copper pads), conductive vias (e.g., copper vias), or combinations thereof. The bonding layer 321 may be formed by depositing a dielectric material on the semiconductor die 350 and the insulating material 356 using a CVD process (e.g., a plasma enhanced CVD process or other suitable process); patterning the dielectric material to form the bonding layer 321 including openings or through holes; and filling conductive material in the openings or through holes defined in the bonding layer 321 to form the bonding pads 323 embedded in the bonding layer 321.

FIG. 18 illustrates the bonding of the semiconductor die 250 and one or more dummy dies 358 to the structure shown previously in FIG. 17. In accordance with some embodiments, the dummy dies 358 may be placed to provide structural support to the integrated chip package 20, and reduce a risk of warping or cracking. In some embodiments, the dummy dies 358 may be formed from a semiconductor material such as silicon, silicon carbide, gallium arsenide, gallium phosphide, indium phosphide, indium arsenide, indium antimonide, the like, or combinations thereof. In some embodiments, the dummy dies 358 may be formed from a dielectric material such as a ceramic material, quartz, another electrically inert material, the like, or combinations thereof. In some embodiments, the dummy dies 358 may be a metal or metal alloy, such as a tin-nickel alloy, or the like. In some embodiments, the dummy dies 358 are formed from two or more different materials, such as multiple layers of different materials. In accordance with some embodiments, the dummy dies 358 may be substantially free of any active devices, functional circuits, or the like. For example, the dummy dies 358 may include a dummy die substrate (e.g., a bulk silicon substrate) and a dummy die bonding layer 138. The dummy die bonding layer 138 may comprise an oxide (e.g., silicon oxide) and may be used to bond the dummy dies 358 to the bonding layer 321 disposed over the semiconductor die 350 and the insulating material 356. The dummy die bonding layer 138 of each dummy die 358 may be bonded to the bonding layer 321 using a fusion bonding process that is similar to the fusion bonding process used to bond the carrier substrate 352 to the semiconductor die 350 that was described previously in FIG. 17.

Still referring to FIG. 18, the semiconductor die 250 is bonded to the integrated chip package 20, for example, in a hybrid bonding configuration. The semiconductor die 250 may also be referred to subsequently as a top die. The semiconductor die 250 is disposed face down and bonded to the semiconductor die 350, such that the front side of the semiconductor die 250 is bonded to the back side of the semiconductor die 350. The semiconductor die 250 is bonded to the bonding layer 321 on the back side of the semiconductor die 350 and the bonding pads 323 in the bonding layer 321. For example, the bonding layer 121 of the semiconductor die 150 may be directly bonded to the bonding layer 321 on the semiconductor die 350, and the bonding pads 123 of the semiconductor die 150 may be directly bonded to the bonding pads 323 of the semiconductor die 350. In an embodiment, the bond between the bonding layer 121 and the bonding layer 321 may be an oxide-to-oxide bond, or the like. The hybrid bonding process further directly bonds the bonding pads 123 of the semiconductor die 150 to the bonding pads 323 on the semiconductor die 350 through direct metal-to-metal bonding. The hybrid bonding process may be similar to that described previously for the bonding of the semiconductor die 150 to the wafer 200 in FIG. 7. Thus, electrical connection between the semiconductor die 150 and the semiconductor die 350 is provided by the physical connection of the bonding pads 123 to the bonding pads 323.

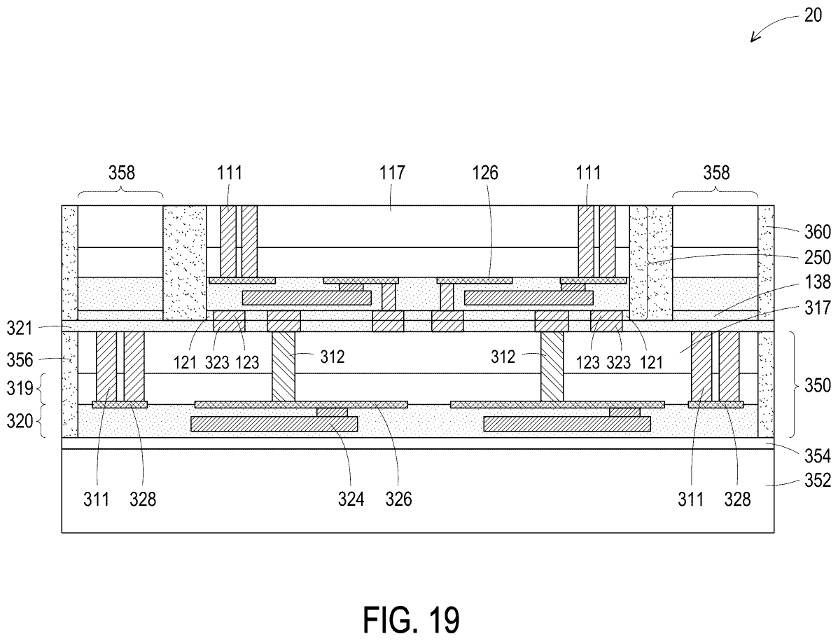

In FIG. 19, an insulating material 360 (also referred to as a gapfill material or an encapsulant) is formed over the semiconductor die 250, the bonding layer 321, and the dummy dies 358, in order to encapsulate the semiconductor die 250, as well as to encapsulate each of the dummy dies 358. The insulating material 360 fills the gaps between the semiconductor die 250 and respective dummy dies 358. In accordance with some embodiments, the insulating material 360 may be an oxide (e.g., silicon dioxide), or the like. The insulating material 360 may be formed by spin-coating, high-density CVD, or the like. After the formation of the insulating material 360, a planarization process may be performed to remove excess material of the insulating material 360 over the semiconductor die 250 and the dummy dies 358, so as to expose top surfaces of the substrate 117, the dummy TSVs 111, and the dummy dies 358. After the planarization process, the top surfaces of the substrate 117, the dummy TSVs 111, and the dummy dies 358 may be level (within process variations) with top surfaces of the insulating material 360. The planarization process may be a grinding process, a chemical mechanical polish (CMP) process, or the like. However, any suitable planarization process may be utilized.

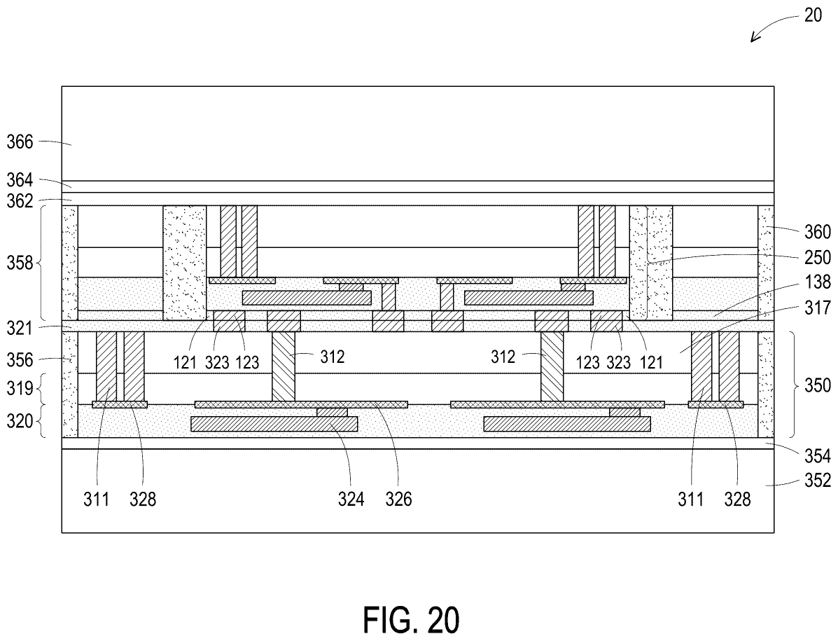

In FIG. 20, a carrier substrate 366 is bonded to top surfaces of the insulating material 360, the dummy dies 358, and the semiconductor die 250 (e.g., the back side of the semiconductor die 250). The carrier substrate 366 may include a bulk substrate (e.g., a semiconductor substrate) or a wafer, and may be formed of a material such as silicon, ceramic, glass, or the like. The carrier substrate 366 is bonded to the insulating material 360, the dummy dies 358, and the back side of the semiconductor die 250 using a suitable technique such as fusion bonding, or the like. For example, in various embodiments, the carrier substrate 366 may be bonded to the semiconductor die 250, the dummy dies 358, and the insulating material 360 using a bonding layer 364 on a surface of the carrier substrate 366 and a bonding layer 362 on surfaces of the insulating material 360, the dummy dies 358 and the semiconductor die 250. In some embodiments, the bonding layer 362 and the bonding layer 364 may each comprise silicon oxide formed using a deposition process, such as chemical vapor deposition (CVD), physical vapor deposition (PVD), or the like. In other embodiments, the bonding layer 364 on the carrier substrate 366, and the bonding layer 362 on the dummy dies 358 and the semiconductor die 250 may be formed by the thermal oxidation of silicon surfaces on the carrier substrate 366, the dummy dies 358, and the semiconductor die 250.

Prior to bonding, one or more of the bonding layers 362/364 may be subjected to a surface treatment. The surface treatment may include a plasma treatment. The plasma treatment may be performed in a vacuum environment. After the plasma treatment, the surface treatment may further include a cleaning process (e.g., a rinse with deionized water, or the like) that may be applied to at least one of the bonding layers 362/364. The carrier substrate 366 is then aligned with the insulating material 360, the dummy dies 358, and the semiconductor die 250, and pressed against each other at a temperature that is, for example, between about 21 degrees and about 25 degrees, such that the carrier substrate 366 is in contact with and bonded to the insulating material 360, the semiconductor die 250, and the dummy dies 358. The bonding process may be strengthened by a subsequent annealing step. For example, this may be done by heating the semiconductor die 250, the insulating material 360, the dummy dies 358, and the carrier substrate 366 to a temperature in a range from 140° C. to 500° C.

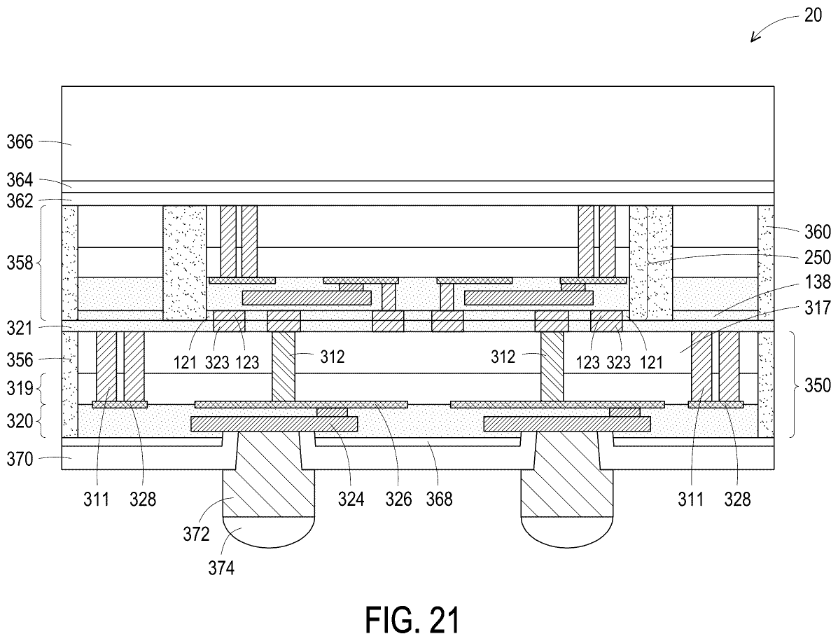

FIG. 21 illustrates the removal of the carrier substrate 352. In an embodiment, the carrier substrate 352, along with the bonding layer 354, may be removed through a planarization process to expose the dielectric layer 320 and the insulating material 356. The planarization process may be a grinding process, a CMP process, or the like. However, any suitable planarization process may be utilized. A dielectric layer 368 is then formed on a bottom surface of the integrated chip package 20, such as on the exposed surfaces of the dielectric layer 320 and the insulating material 356. In an embodiment, the dielectric layer 368 may comprise silicon oxide, silicon nitride, silicon oxynitride, a polymer, or the like and be deposited by PVD, CVD, ALD, or the like.

After the formation of the dielectric layer 368, first openings are formed in the dielectric layer 368 to expose surfaces of the contact pads 324. The first openings may be formed using acceptable etching techniques. After the formation of the first openings, dielectric layer 370 is formed on the dielectric layer 368 and in the first openings. For example the dielectric layer 370 may be formed on sidewalls in the first openings and on the exposed surfaces of the contact pads 324 within the first openings. The dielectric layer 370 may comprise a polymer, such as polyimide (PI)), or the like. The dielectric layer 370 may be formed using spin coating, lamination, or the like.

After the formation of the dielectric layer 370, lateral portions of the dielectric layer 370 within the first openings are removed so as to re-expose the contact pads 324. The lateral portions of the dielectric layer 370 may be removed using acceptable etching techniques. After the removal of the lateral portions of the dielectric layer 370, remaining portions of the dielectric layer 370 remain disposed on sidewalls of each of the first openings.

Referring further to FIG. 21, under bump metallurgies (UBMs) 372 are formed in the first openings for external connection to the contact pads 324. The UBMs 372 have bump portions on and extending along the major surface of the dielectric layer 370, and have via portions extending through the dielectric layer 370 and the dielectric layer 368 to physically and electrically couple the contact pads 324. As a result, the UBMs 372 are electrically coupled to the TSVs 312, and the metallization patterns 326 of the semiconductor die 350. In addition, the UBMs 372 are also electrically connected to the metallization patterns 126 and the contact pads 124 of the semiconductor die 250, through the BPVs 130, the bonding pads 123, and the bonding pads 323. The UBMs 372 may be formed of the same material as the metallization patterns 126 and 326.

After the formation of the UBMs 372, conductive connectors 374 are formed on the UBMs 372. The conductive connectors 374 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 374 may include a conductive material such as solder, copper, aluminum, gold, nickel, silver, palladium, tin, the like, or a combination thereof. In some embodiments, the conductive connectors 374 are formed by initially forming a layer of solder through evaporation, electroplating, printing, solder transfer, ball placement, or the like. Once a layer of solder has been formed on the structure, a reflow may be performed in order to shape the material into the desired bump shapes. The conductive connectors 374 may be used to couple and electrically connect the integrated chip package 20 to other external devices, such as for example, a package substrate, or the like.

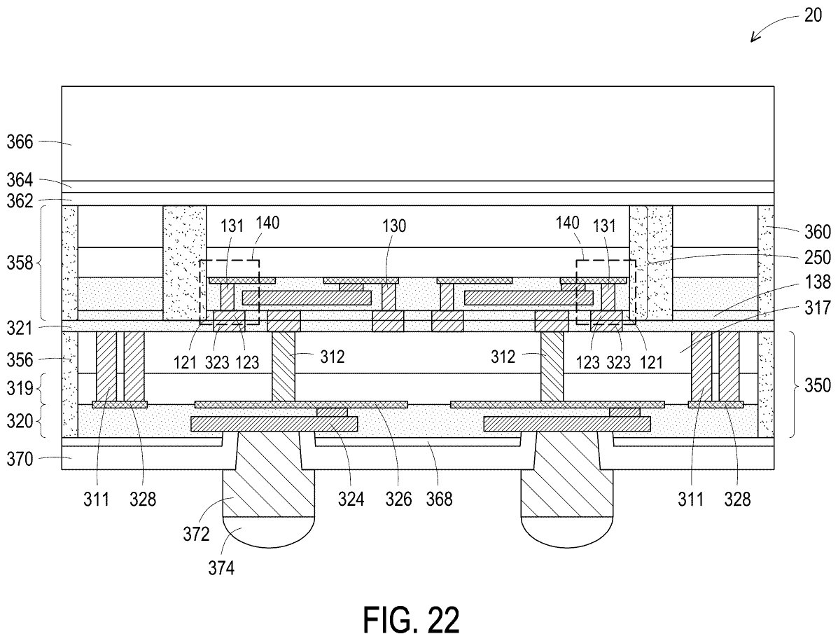

FIG. 22 illustrates a cross-sectional view of intermediate steps during a process for forming the integrated chip package 20, in accordance with alternate embodiments. Unless specified otherwise, like reference numerals in this embodiment (and subsequently discussed embodiments) represent like components in the embodiment shown in FIGS. 10A through 21 formed by like processes. Accordingly, the process steps and applicable materials may not be repeated herein.

The embodiment shown in FIG. 22 shows the integrated chip package 20 that comprises the semiconductor die 250, wherein the semiconductor die 250 does not comprise any dummy TSVs 111. Instead, bonding pads 123 in peripheral regions 140 (which may also be referred to as edge regions subsequently) of the semiconductor die 250 may be formed. These bonding pads 123 in the peripheral regions 140 serve as dummy bonding pads, and may not serve a functional electrical or interconnect purpose. In addition, dummy bond pad vias (BPVs) 131 may be formed in the peripheral regions 140 of the dielectric layer 120 of the semiconductor die 250. Each dummy BPV 131 may be in physical contact with a respective bonding pad 123 in the peripheral regions 140. The dummy BPVs 131 may be formed in a similar manner and using similar materials as the BPVs 130 described previously, and may not serve a functional electrical or interconnect purpose. In some embodiments, only the bonding pads 123 in the peripheral regions 140 are formed, and the dummy BPVs 131 are not formed.

The embodiments of the present disclosure have some advantageous features. The embodiments include a method for the formation of an integrated chip package that comprises bonding a semiconductor die (e.g., a top die) to a semiconductor wafer (e.g., a bottom die). The top die may comprise dummy through substrate vias (TSVs) that are disposed at peripheral regions (also referred to as edge regions) of the top die. The semiconductor wafer may also comprise dummy through substrate vias (TSVs) that are disposed at peripheral regions (also referred to as edge regions) of the semiconductor wafer. For example, the dummy TSVs may be uniformly distributed within the top die along the edge regions of the top die. The dummy TSVs may be also uniformly distributed within the semiconductor wafer along the edge regions of the semiconductor wafer. The dummy TSVs comprise a metal and are used to increase a metal density of the edge regions of the top die, and reduce a difference between the metal density of the edge regions of the top die and a metal density of a central region of the top die. As a result, a difference between a co-efficient of thermal expansion (CTE) of the edge regions of the top die and a co-efficient of thermal expansion (CTE) of the central region of the top die is reduced. This allows for a reduction of thermal stresses that are generated within the top die, and results in a reduced risk of warping of the top die. This ensures that the edge regions of the top die do not curve (also referred to as tilt) upwards away from a top surface of the semiconductor wafer, and allows adequate physical contact between bonding pads of the edge regions of the top die, and respective bonding pads of the semiconductor wafer. In this way, bonding between the top die and the semiconductor wafer is improved, and device reliability is enhanced. In addition, preventing the edge regions of the top die from tilting upwards away from the top surface of the semiconductor wafer reduces a risk of forming a gap between the top die and the semiconductor wafer. As a result, a risk of chemical damage or moisture damage to the exposed surfaces of the top die and the semiconductor wafer within the gap during subsequently performed processing steps is reduced.

In accordance with an embodiment, a package includes a first die over and bonded to a first side of a second die, where the second die includes a first substrate; a first interconnect structure over the first substrate; a seal ring disposed within the first interconnect structure; first dummy through substrate vias (TSVs) extending through edge regions of the first substrate of the second die and in physical contact with the seal ring; and functional TSVs extending through a central region of the first substrate of the second die. In an embodiment, the second die further includes metallization patterns disposed in the first interconnect structure, where the seal ring surrounds the metallization patterns, and where the first dummy TSVs and the functional TSVs extend partially through the first interconnect structure. In an embodiment, the first dummy TSVs are disposed around the functional TSVs, and where the first dummy TSVs are disposed under and are overlapped by the seal ring. In an embodiment, the package further includes conductive connectors on a second side of the second die, the conductive connectors being electrically coupled to the functional TSVs and the metallization patterns. In an embodiment, a concentration of the first dummy TSVs under corner regions of the seal ring is higher than a concentration of the first dummy TSVs under other regions of the seal ring. In an embodiment, the second die further includes second dummy TSVs that extend through the edge regions of the second die, where the second dummy TSVs are not in physical contact with the seal ring. In an embodiment, the second dummy TSVs are disposed adjacent to corner regions of the seal ring, and where in a top-down view, the second dummy TSVs are disposed within an inner perimeter of the seal ring.

In accordance with an embodiment, a package includes a first die including a first substrate; a first interconnect structure on the first substrate; a first seal ring disposed within the first interconnect structure; and first dummy through substrate vias (TSVs) extending through edge regions of the first substrate of the first die, where the first dummy TSVs overlap the first seal ring; and a second die disposed below the first die, the first die being bonded to a first side of the second die, the second die including a second substrate; functional TSVs extending through a central region of the second substrate of the second die; a second interconnect structure on the second substrate; a second seal ring disposed within the second interconnect structure; and second dummy TSVs extending through edge regions of the second substrate of the second die, where the second dummy TSVs are disposed to be around the functional TSVs. In an embodiment, the second dummy TSVs overlap the second seal ring, where the first dummy TSVs are in physical contact with the first seal ring, and the second dummy TSVs are in physical contact with the second seal ring. In an embodiment, the second die further includes third dummy TSVs disposed adjacent to corner regions of the second seal ring, where in a top-down view, the third dummy TSVs are disposed within an inner perimeter of the second seal ring. In an embodiment, the second die further includes first metallization patterns disposed in the second interconnect structure, and where the second seal ring surrounds the first metallization patterns. In an embodiment, the package further includes conductive connectors on a second side of the second die, the conductive connectors being electrically coupled to the functional TSVs and the first metallization patterns. In an embodiment, the second dummy TSVs are uniformly distributed along the second seal ring. In an embodiment, the second dummy TSVs extend through the second substrate and the second interconnect structure, and where the first dummy TSVs extend partially through the first interconnect structure. In an embodiment, each of the second dummy TSVs extends through a gap between adjacent portions of the second seal ring in the second interconnect structure.

In accordance with an embodiment, method of manufacturing a semiconductor device includes forming a top die, where forming the top die includes forming a device layer on a front side of a substrate; forming first dummy through substrate vias (TSVs) that extend through edge regions of the device layer and the substrate; forming functional (TSVs) that extend through central regions of the device layer and the substrate, where the first dummy TSVs are disposed around the functional TSVs; and forming an interconnect structure over the front side of the substrate, where forming the interconnect structure includes forming a seal ring that overlaps and is in physical contact with the first dummy TSVs; and bonding the top die to a bottom die, where bonding the top die to the bottom die includes bonding a first bond pad of the top die to a second bond pad of the bottom die. In an embodiment, the method further includes forming second dummy TSVs that extend through edge regions of the device layer and the substrate, and where after forming the interconnect structure over the front side of the substrate, the second dummy TSVs are not in physical contact with the seal ring. In an embodiment, the second dummy TSVs are disposed adjacent to corner regions of the seal ring, where in a top-down view, the second dummy TSVs are disposed within an inner perimeter of the seal ring. In an embodiment, the first dummy TSVs are uniformly distributed along the seal ring, and around the functional TSVs. In an embodiment, the first dummy TSVs are non-uniformly distributed along the seal ring, and around the functional TSVs.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, the method comprising:
forming a top die, wherein forming the top die comprises:
forming a device layer on a front side of a substrate;
forming first dummy through substrate vias (TSVs) and second dummy TSVs that extend through edge regions of the device layer and the substrate;
forming functional TSVs that extend through central regions of the device layer and the substrate, wherein the first dummy TSVs and the second dummy TSVs are disposed around the functional TSVs; and
forming an interconnect structure over the front side of the substrate, wherein forming the interconnect structure comprises forming a seal ring that overlaps and is in physical contact with the first dummy TSVs, wherein the seal ring is not in physical contact with the second dummy TSVs.

2. The method of claim 1, further comprising:
bonding the top die to a bottom die, wherein bonding the top die to the bottom die comprises bonding a first bond pad of the top die to a second bond pad of the bottom die.

3. The method of claim 1, wherein the second dummy TSVs are disposed adjacent to corner regions of the seal ring.

4. The method of claim 3, wherein in a top-down view, the second dummy TSVs are disposed within an inner perimeter of the seal ring.

5. The method of claim 3, wherein the first dummy TSVs are non-uniformly distributed along the seal ring.

6. The method of claim 3, wherein each of the second dummy TSVs is disposed adjacent to a corresponding corner region of the seal ring.

7. The method of claim 3, wherein at least two second dummy TSVs of the second dummy TSVs are disposed adjacent to each corner region of the seal ring.

8. The method of claim 1, wherein the first dummy TSVs and the second dummy TSVs comprise copper, tungsten, aluminum, silver, or gold.

9. A method of manufacturing a semiconductor device, the method comprising:
forming a top die, wherein forming the top die comprises:
forming a device layer on a front side of a substrate;
forming functional through substrate vias (TSVs) that extend through central regions of the device layer and the substrate;
forming first dummy TSVs that extend through edge regions of the device layer and the substrate;
forming second dummy TSVs that extend through the edge regions of the device layer and the substrate, wherein the first dummy TSVs are disposed around the functional TSVs and the second dummy TSVs, and wherein the second dummy TSVs are disposed between the functional TSVs and the first dummy TSVs; and
bonding the top die to a bottom die, wherein bonding the top die to the bottom die comprises bonding a first bond pad of the top die to a second bond pad of the bottom die.

10. The method of claim 9, further comprising:
forming an interconnect structure over the front side of the substrate, wherein forming the interconnect structure comprises forming a seal ring that overlaps and is in physical contact with the first dummy TSVs.

11. The method of claim 10, wherein the seal ring is not in physical contact with the second dummy TSVs.

12. The method of claim 11, wherein the second dummy TSVs are disposed adjacent to corner regions of the seal ring.

13. The method of claim 11, wherein in a top-down view, the second dummy TSVs are disposed within an inner perimeter of the seal ring.

14. The method of claim 11, wherein each of the second dummy TSVs is disposed adjacent to a corresponding corner region of the seal ring.

15. A package comprising:
a first die over and bonded to a first side of a second die, wherein the second die comprises:
a first substrate;
a first interconnect structure over the first substrate, wherein the first interconnect structure comprises a seal ring;
first dummy through substrate vias (TSVs) extending through edge regions of the first substrate of the second die and in physical contact with the seal ring;
functional TSVs extending through a central region of the first substrate of the second die; and
second dummy TSVs extending through the edge regions of the first substrate of the second die, wherein the first dummy TSVs are disposed around the functional TSVs and the second dummy TSVs, and wherein the second dummy TSVs are disposed between the functional TSVs and the first dummy TSVs.

16. The package of claim 15, wherein the second dummy TSVs are not in physical contact with the seal ring.

17. The package of claim 15, wherein a concentration of the first dummy TSVs under corner regions of the seal ring is higher than a concentration of the first dummy TSVs under other regions of the seal ring.

18. The package of claim 15, wherein the second dummy TSVs are disposed adjacent to corner regions of the seal ring.

19. The package of claim 18, wherein in a top-down view, the second dummy TSVs are disposed within an inner perimeter of the seal ring.

20. The package of claim 15, wherein the first dummy TSVs and the second dummy TSVs comprise copper, tungsten, aluminum, silver, or gold.
